(19) United States
(12) Patent Application Publication
(10) Pub. No.: US 2026/0114083 A1
(43) Pub. Date: Apr. 23, 2026

(54) QUANTUM DOT CASCADE LIGHT EMITTING DEVICES

(71) Applicant: The University of Chicago, Chicago, IL (US)

(72) Inventors: Philippe Guyot-Sionnest, Chicago, IL (US); Xingyu Shen, Chicago, IL (US); Augustin Caillas, Chicago, IL (US)

(21) Appl. No.: 19/416,016

(22) Filed: Dec. 11, 2025

Related U.S. Application Data
(63) Continuation-in-part of application No. PCT/US24/33396, filed on Jun. 11, 2024.
(60) Provisional application No. 63/472,738, filed on Jun. 13, 2023.

(51) Int. Cl. H10H 20/812; H10H 20/823; H10H 20/831

(52) U.S. Cl. CPC H10H 20/812; H10H 20/823; H10H 20/831

(57) ABSTRACT

Methods of generating light are provided comprising applying an electrical bias to an active region of a quantum dot cascade light emitting device comprising: the active region comprising a film of close-packed, doped, colloidal quantum dots, the quantum dots comprising a core semiconductor characterized by an energy band having quantum states defining an intraband transition between a high energy quantum state and a low energy quantum state, and a pair of electrodes configured to apply the electrical bias, wherein the active region emits light under the electrical bias as carriers undergo the intraband transitions in the core semiconductor of quantum dots in the film, tunnel to other quantum dots in the film, and undergo additional intraband transitions in the core semiconductor of the other quantum dots in the film. The quantum dot cascade light emitting devices are also provided.

### CROSS-REFERENCE TO RELATED APPLICATIONS

The present application is a continuation-in-part of International Application No. PCT/US24/33396 that was filed on Jun. 11, 2024, which claims priority to U.S. provisional patent application No. 63/472,738 that was filed Jun. 13, 2023, the entire contents of both of which are incorporated herein by reference.

### REFERENCE TO GOVERNMENT RIGHTS

This invention was made with government support under DE-SC0023210 awarded by the U.S. Department of Energy, 2226311 awarded by the National Science Foundation, and W911NF-22-1-0157 awarded by the Army Research Laboratory-Army Research Office. The government has certain rights in the invention.

### BACKGROUND

Mid-infrared (IR) light sources are needed for applications like gas sensing, environmental monitoring, and spectroscopy. One example is the monitoring of greenhouse gas emissions, including methane, in drilling and fuel-production settings. Thermal mid-IR light sources are widely used, e.g., in conjunction with detectors to monitor CO₂, CO, and hydrocarbons in automotive exhaust systems. However, the broadband emission and high-power consumption are poorly suited for compact and portable applications. Non-thermal mid-IR light sources make use of epitaxial and other microfabricated semiconductor materials to provide electrically robust solutions using moderate power. However, the efficiencies are still rather low, particularly for wavelengths greater than 1 μm.

### SUMMARY

Provided are quantum dot cascade light emitting devices comprising an active region comprising colloidal quantum dots and a pair of electrodes configured to apply an electrical bias across the active region. As described in detail below, the active region is configured to emit light therefrom via a quantum cascade process upon application of the electrical bias. The present disclosure is based, at least in part, on the remarkable and unexpected discovery that quantum cascade light emission may be achieved by an active region based on colloidal quantum dots. Although quantum cascade light emission has been achieved in the quantum wells of epitaxial multilayer semiconductor structures, this has required extensive band engineering, involving a critical selection of composition, thicknesses, and arrangement of the quantum wells and barriers in such structures. In sharp contrast, embodiments of the present quantum dot cascade light emitting devices achieve unexpectedly high electroluminescence external quantum efficiencies (EL EQE) from drop-casted films of colloidal quantum dots. As one example, Example 1, below, describes fabrication and testing of an illustrative embodiment of a quantum dot cascade light emitting device that emitted light at 5 μm with 4.5% EL EQE at 2 A/cm². In another example, Example 2, below, describes fabrication and testing of another illustrative embodiment of quantum dot cascade light emitting device that emitted light at 5 μm with 15% EL EQE at 11 A/cm².

An embodiment 1 is a method of generating light, the method comprising applying an electrical bias to an active region of a quantum dot cascade light emitting device comprising: the active region comprising a film of close-packed, doped, colloidal quantum dots, the quantum dots comprising a core semiconductor characterized by an energy band having quantum states defining an intraband transition between a high energy quantum state and a low energy quantum state, and a pair of electrodes configured to apply the electrical bias, wherein the active region emits light under the electrical bias as carriers undergo the intraband transitions in the core semiconductor of quantum dots in the film, tunnel to other quantum dots in the film, and undergo additional intraband transitions in the core semiconductor of the other quantum dots in the film.

An embodiment 2 is the method according to embodiment 1, wherein the energy band is dispersive by more than 0.3 eV and has a minimum lower than −3 eV with respect to vacuum. An embodiment 3 is the method according to embodiment 2, wherein the high energy quantum state of the intraband transition has a greater degeneracy than the low energy quantum state of the intraband transition.

An embodiment 4 is the method according to any of the preceding embodiments, wherein the quantum dots are characterized by a doping level n of less than 2. An embodiment 5 is the method according to embodiment 4, wherein the doping level nis in a range of from 0.1 to 1. An embodiment 6 is the method according to embodiment 5, wherein the range is from 0.5 to 0.7.

An embodiment 7 is the method according to any of the preceding embodiments, wherein the quantum dots are core-shell quantum dots further comprising a shell semiconductor around the core semiconductor. An embodiment 8 is the method according to embodiment 7, wherein the shell semiconductor has a shell thickness of less than 10 monolayers of the shell semiconductor. An embodiment 9 is the method according to embodiment 8, wherein the shell thickness is in a range of from 1 to 5 monolayers of the shell semiconductor.

An embodiment 10 is the method according to any of the preceding embodiments, wherein the light is mid-infrared light.

An embodiment 11 is the method according to any of the preceding embodiments, wherein the light has a wavelength in a range of from 4 μm to 7 μm.

An embodiment 12 is the method according to any of the preceding embodiments, wherein the active region has a channel length of at least 1 μm.

An embodiment 13 is the method according to any of the preceding embodiments, wherein the electrical bias is greater than 10 V.

An embodiment 14 is the method according to any of the preceding embodiments, wherein the electrical bias is in a range of from greater than 10 V to 30 V.

An embodiment 15 is the method according to any of the preceding embodiments, wherein the quantum dot cascade light emitting device exhibits greater electroluminescent external quantum efficiency (EL EQE) as compared to photoluminescence external quantum efficiency (PL EQE). An embodiment 16 is the method according to embodiment 15, wherein the EL EQE is at least 50 times greater than the PL EQE.

An embodiment 17 is the method according to any of the preceding embodiments, wherein the quantum dot cascade light emitting device further comprises a planar interdigitated electrode layer below a surface of the active region, the planar interdigitated electrode layer comprising the pair of electrodes. An embodiment 18 is the method according to embodiment 17, wherein the quantum dot cascade light emitting device further comprises a spacer layer below the planar interdigitated electrode layer and a back reflector layer below the spacer layer.

An embodiment 18 is the method according to any of the preceding embodiments, wherein the quantum dot cascade light emitting device emits the light at constant current.

An embodiment 19 is a quantum dot cascade light emitting device comprising an active region comprising a film of close-packed, doped, colloidal quantum dots, the quantum dots comprising a core semiconductor characterized by an energy band having quantum states defining an intraband transition between a high energy quantum state and a low energy quantum state; and a pair of electrodes configured to apply an electrical bias to the active region, wherein the active region is configured to emit light under the electrical bias as carriers undergo the intraband transitions in the core semiconductor of quantum dots in the film, tunnel to other quantum dots in the film, and undergo additional intraband transitions in the core semiconductor of the other quantum dots in the film.

An embodiment 20 is the device according to embodiment 19, wherein the device does not include both a source of electrons and a source of holes.

An embodiment 21 is the device according to any of embodiments 19-20, wherein the device does not comprise carbon nanotubes.

An embodiment 22 is the device according to any of embodiments 19-21, wherein the quantum dots do not comprise Hg.

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings.

FIG. 1A shows a perspective view of a schematic of a quantum dot cascade light emitting device according to an illustrative embodiment. FIG. 1B shows the energy alignment of the device. FIG. 1C shows a TEM of HgSe cores in the device; the scale bar is 20 nm. FIG. 1D shows a TEM of HgSe/CdSe colloidal core-shell quantum dots in the device; the scale bar is 20 nm. FIG. 1E shows cross-section SEM of the device; the scale bar is 200 nm. FIG. 1F shows EL spectra of the device at different peak currents. The emission peak is centered around 5 μm, which is characteristic of the intraband transition 1Sₑ-1Pₑ in the cores of the HgSe/CdSe colloidal core-shell quantum dots. The peak intensity grew smoothly with current. FIG. 1G shows the Current-Voltage-Radiance relationship as measured in the device. The device was tested using a sine wave current source at 9 kHz. The peak current, peak voltage, and peak radiance are shown. The shadow area was calculated using the Poole-Frenkel model described in Example 1, below. FIG. 1H shows the power conversion efficiency (PCE) of the device. FIG. 1I shows EL emission as a function of time using a peak current of +10 mA.

FIG. 2A shows the EQE of the device of FIG. 1A vs current. FIG. 2B shows EQE of a comparative undoped HgTe quantum dot device vs current. FIG. 2C shows photoluminescence (PL) and EL spectra of the device of FIG. 1A and the comparative device. Spectra were normalized to the number of absorbed photons or injected electrons, and the intensities were comparable, noting that the EL signal was divided by 50 for the device of FIG. 1A. FIG. 2D shows the EL/PL ratio from HgSe/CdSe colloidal core-shell quantum dots with different doping. FIG. 2E shows the EL/PL ratio of HgSe/CdSe colloidal core-shell quantum dots with different shell thickness. FIG. 2F shows the EL/PL HgSe/CdSe colloidal core-shell quantum dots having different total thicknesses of the active region.

FIG. 3 shows a schematic of an energy band diagram of an active region comprising colloidal core-shell quantum dots (under electrical bias) of an illustrative device similar to the device of FIG. 1A. Quantum cascade light emission (the emission of multiple photons from a single electron as it tunnels from quantum dot to quantum dot) is schematically illustrated.

FIG. 4A shows a plot of radiance-current from the illustrative device of FIG. 1A. FIG. 4B shows a plot of radiance-voltage from the device. FIG. 4C shows a plot of radiance-input power from the device. The device is driven by a sine wave current source. Input electrical power is calculated by current×bias/2. The shadow area is calculated using the Poole-Frenkel model described in Example 1.

FIG. 5A shows PL and EL spectra from an illustrative quantum dot cascade light emitting device as shown in the inset in the figure and fabricated as described in Example 2. The 2,000 cm⁻¹ (5 μm) peak is characteristic of the 1Sₑ-1Pₑ intraband transition of the HgSe cores. The PL is excited by an 808-nm diode laser. The EL is excited by a current source modulated by a sine wave. All of the measurements are performed at room temperature. FIG. 5B shows the PCE of devices similar to that shown in FIG. 5A but using interdigitated electrodes having different gap dimensions. Error bars are from EL intensity measurements.

FIG. 6A shows a perspective view of a schematic of an illustrative quantum dot cascade light emitting device fabricated as described in Example 2. In this embodiment, the substrate includes Au as a back reflector, a 1.2 μm SiO₂ spacer, and metallic gratings having a 1.7 μm width and defining 1.7 μm gaps. FIG. 6B shows the EL spectrum from the device. FIG. 6C shows the EQE and the PCE of the device as a function of bias voltage.

FIG. 7A shows EL spectra at different currents from an illustrative quantum dot cascade light emitting device fabricated as described in Example 3. FIG. 7B shows the EQE of the device as a function of current. FIG. 7C shows the PCE of the device as a function of current.

FIG. 8A shows EL spectra at different currents from an illustrative quantum dot cascade light emitting device fabricated as described in Example 3. FIG. 8B shows the EQE and PCE of the device as a function of current.

FIG. 9A shows an illustrative quantum dot cascade light emitting device fabricated as described in Example 4 (i.e., bowtie device). The inset depicts the 3.8 μm×3.2 μm unitary cell of the bowtie antenna array. FIG. 9B shows a map of the PLQY across the device, considering the best dipole orientation at each position. FIG. 9C shows a map of the electrical power density P=J×E_{V} in the device under 1V bias. FIG. 9D shows electroluminescence spectral power density collected through F/2 optics under 3 mW input electrical power for the bowtie device and for a reference device without optical enhancement (see FIG. 13). The spectrum of the reference device is multiplied by 430 for clarity. FIG. 9E shows polarization dependence of the electroluminescence of the bowtie device under 3 mW input electrical power. The TM and TE polarization correspond to light polarized along the X-axis and Y-axis respectively.

FIG. 10A shows a SEM image of a bowtie antenna without the colloidal quantum dots. The contrast difference between the two parts of the antenna originates from electrical charge build up under the e-beam. FIG. 10B shows EL spectra recorded for increasing bias. FIG. 10C shows the polarization dependence of the EL spectrum. TM corresponds to emission polarized perpendicular to the antenna (x-axis) and TE corresponds to emission polarized along the antenna (y-axis). FIG. 10D shows I-V characteristics of the device and emitted power as a function of bias. FIG. 10E shows EQE and PCE of the device as a function of bias. FIG. 10F shows device stability over 1 hour of continuous use with 0.5 mA applied AC current.

FIG. 11A shows EL response of the bowtie device under 1 μs voltage pulses at 5V. Pulse frequency is 1 kHz. The emitted signal is measured with an MCT detector and visualized with an oscilloscope, averaged 1024×. FIG. 11B shows EL rise time.

FIG. 12 shows the detailed geometric parameters of the metallic structure of the bowtie device.

FIG. 13 shows the detailed geometric parameters of the interdigitated gold electrodes of the reference device.

### DETAILED DESCRIPTION

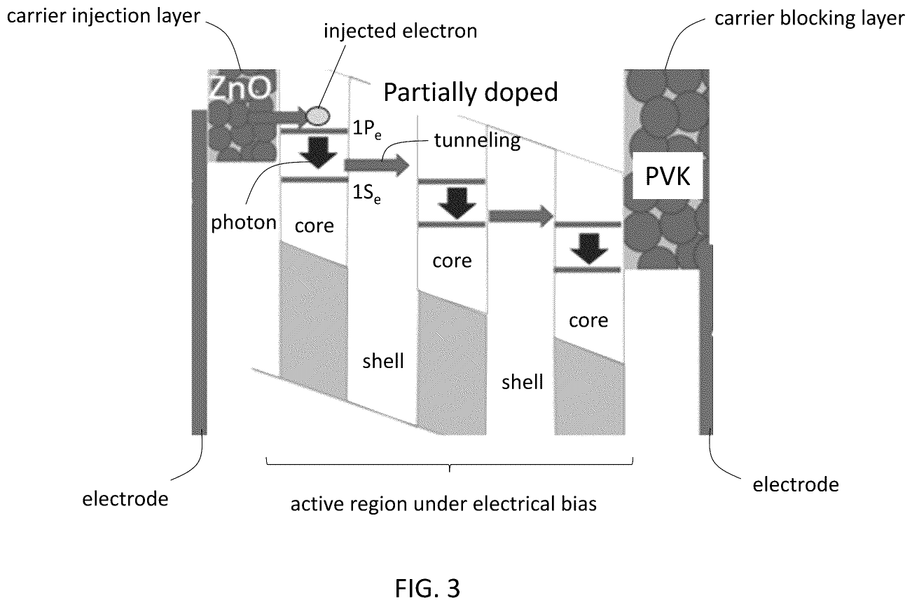

Provided are quantum dot cascade light emitting devices comprising an active region comprising colloidal quantum dots; and a pair of electrodes configured to apply an electrical bias across the active region. As described in detail below with reference to certain physical/chemical characteristics of the active region and the colloidal quantum dots therein, the active region of the present devices is configured to emit light via a quantum cascade process upon application of the electrical bias. This quantum cascade process is schematically illustrated in FIG. 3 with respect to a single carrier (e.g., an electron) in an illustrative quantum dot cascade light emitting device. Specifically, as the electron travels through the active region due to the electrical bias, light is emitted as the electron undergoes an intraband transition in a core of a first core-shell quantum dot, tunnels to a second core-shell quantum dot, and undergoes a second intraband transition in a core of the second core-shell quantum dot. This electron may undergo many such intraband transitions, emitting light each time, as it travels through the active region, and many electrons may each undergo such intraband transitions, thereby achieving high levels of electroluminescence.

Numerous physical/chemical characteristics of the active region and the colloidal quantum dots therein may be selected to ensure light emission via the cascade process as well as to achieve a desired electrooptical property (e.g., wavelength of light emission, EL EQE, etc., as further described below). These characteristics and guidance for their selection in the present devices are described below.

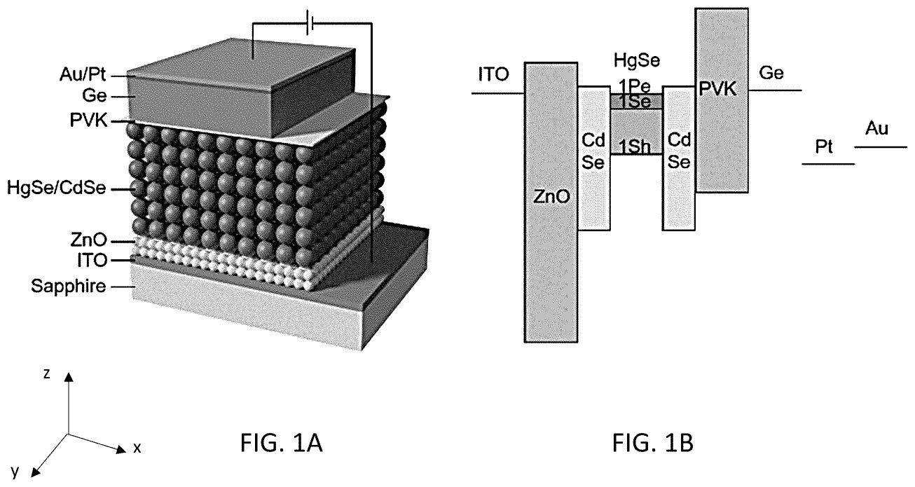

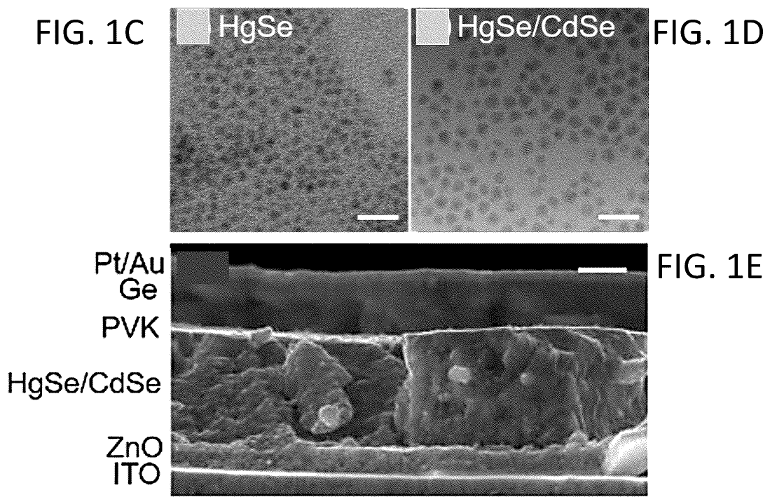

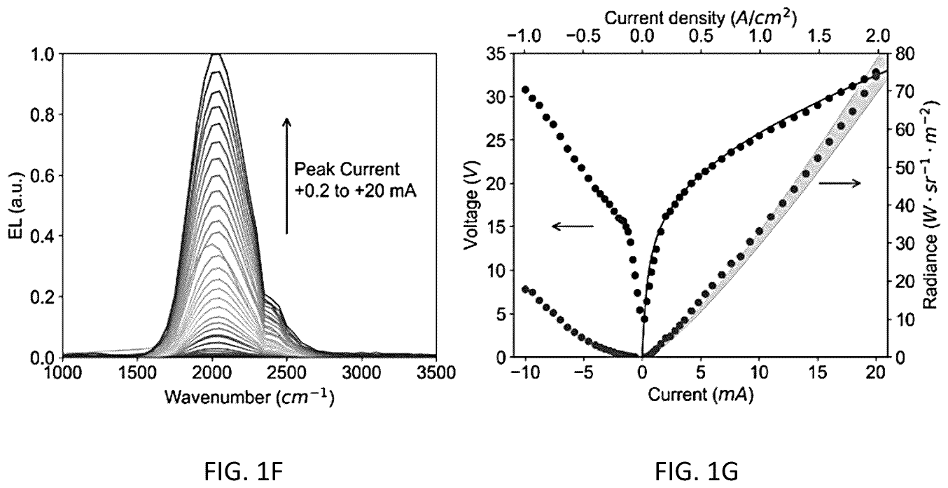

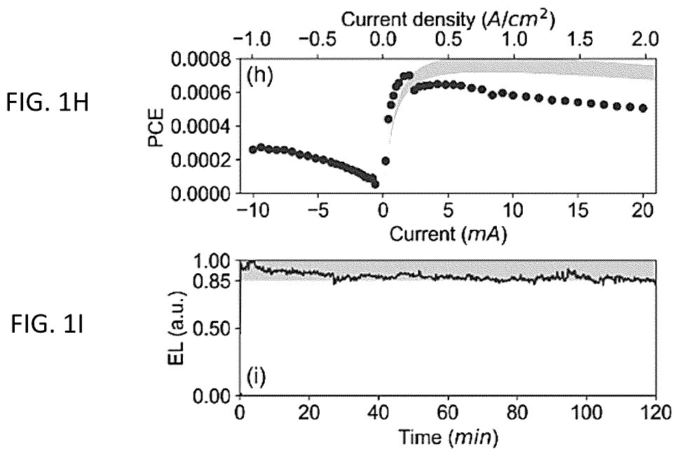

The colloidal quantum dots of the active region comprise or consist of a first type of semiconductor, which may be referred to as a “core semiconductor.” The core semiconductor is a material characterized (i.e., once incorporated as the colloidal quantum dots in the present active regions) by an energy band (e.g., conduction band). The nanosize of the colloidal quantum dots induces quantum states within that energy band. The intraband transitions are the excitation or relaxation of (e.g., electrons) these quantum states. The particular quantum states and the intraband transition depends upon the particular core semiconductor selected as well as the size and shape of the colloidal quantum dot (as further described below). As an illustrative embodiment for spherical colloidal quantum dots, as shown in FIGS. 1A and 3, the quantum states comprise a lowest energy state, |1>, labelled 1Sₑ, and a first higher energy state, |2>, labelled 1Pₑ. The excitation of an electron from |1> to |2> leads to the intraband transition, seen as an infrared absorption. Similarly, an electron relaxing from |2> to |1> leads to the emission of an infrared photon. The wavelength of the light emission depends upon the particular core semiconductor selected as well as the size and shape of the colloidal quantum dot. Desirably, the intraband transition energy covers wavelengths from 12 μm to 2 μm, and is of an energy between 0.1 eV and 0.5 eV. To provide such quantum states within colloidal quantum dots, the energy band of the core semiconductor must be dispersive over at least 0.3 eV. This includes at least 0.5 eV and at least 1 eV. As an illustrative example, a HgSe core semiconductor conduction band is dispersive over 1 eV, and its conduction band minimum is at −5.4 eV with respect to vacuum. HgSe colloidal quantum dots of having a 5 nm diameter exhibit the intraband transition at 0.25 eV and may be readily n-doped. In addition, desirably the higher energy quantum state (e.g., 1Pₑ excited state) of the quantum states involved in the intraband transition has a greater degeneracy than the lower energy quantum state (e.g., 1Sₑ ground state). In the illustrative example shown in FIG. 3, the 1Pₑ state has three times the degeneracy of the 1Sₑ state. Finally, core semiconductors which are resistant to doping (e.g., n-doping), have poorly defined intraband transitions (e.g., due to low energy valleys of the conduction band), and/or have a multiplicity of energy bands, are generally not used.

It is desirable to chemically modify the surface of the colloidal quantum dots so as to protect the cores therein, including to minimize non-radiative energy transfer of electrons traveling through the active region. A variety of chemical modifications may be used to achieve this functionality, including molecular ligands bound (covalently or noncovalently) to surfaces of the colloidal quantum dots (e.g., the core semiconductors); a layer of a second, different type of semiconductor (which may be referred to as a “shell semiconductor”) on surfaces of the core semiconductors; embedding the colloidal quantum dots in a matrix (e.g., a polymer matrix); or combinations thereof. The particular configuration of each type of chemical modification (e.g., composition, surface coverage, thickness, etc.) may be selected to achieve the desired functionality. However, desirably the molecular ligands/shell semiconductor/matrix is substantially transparent (e.g., at least 95%, 98%, or 100% transparent) to the light emitted from the core semiconductor.

Each of the embodiments in the paragraph immediately above may be characterized as providing a protective “shell” on the core semiconductor that generates the desired core intraband transitions. However, the phrase “core-shell” may be used in reference to embodiments in which a layer of a second, different type of semiconductor on the surface of the core semiconductor is used. Nevertheless, it is understood that the phrase “colloidal quantum dots” encompasses each of the various embodiments in the paragraph immediately above. It also encompasses colloidal quantum dots consisting of any of the disclosed core semiconductors without any chemical modifications.

As noted above, when a shell semiconductor is used, the shell semiconductor is a different type of semiconductor from the core semiconductor. As noted above, the shells of such core-shell quantum dots protect the cores therein and minimize non-radiative energy relaxation. As also noted above, the shells of the core-shell quantum dots are desirably substantially transparent to the light emitted due to the core intraband transition. Thus, depending upon the selected core semiconductor, the composition of the shell semiconductor (and the shell thickness as described below) may be selected to achieve these functions. In addition, at the selected shell thickness, the conduction band energy of the shell semiconductor is desirably sufficiently close to the energy of the core intraband transition so that shell is not overly insulating.

It is noted that surfaces of core-shell colloidal quantum dots may also be chemically modified for additional protection, e.g., by using molecular ligands bound to surfaces of the shell semiconductor and/or embedding the core-shell colloidal quantum dots in a matrix.

Illustrative semiconductors which may be used as the core semiconductors include binary semiconductors such as InSb, InAs, InP, InN, GaN, CdSe, CdS, ZnO, HgS, HgSe, HgTe, Ag₂Te, and ternary semiconductors such as CulnSe₂. Illustrative semiconductors which may be used as the shell semiconductors include ZnS, ZnSe, CdS, CdSe, and CdTe. Illustrative core-shell quantum dots which may be used include HgSe (core)/CdSe (shell) quantum dots, HgSe (core)/CdS (shell) quantum dots, InP (core)/ZnS (shell) quantum dots, and CulnSe₂ (core)/ZnS (shell) quantum dots.

In embodiments, the core semiconductor is not CdTe, ZnTe, ZnSe, ZnS, AlN, GaN, AlAs, GaP, Si, Ge, GaP, or a Pb-chalcogenide. In embodiments, the colloidal quantum dots (and the present devices) do not comprise Hg.

The active region may comprise a single type of colloidal quantum dot (all colloidal quantum dots have the same composition) or multiple, different types of colloidal quantum dots.

The colloidal quantum dots of the active region may be characterized by their overall size and overall shape. The term “overall” refers to the total size of the colloidal quantum dots (e.g., for core-shell colloidal quantum dots both the core and the shell). The shell thickness is described separately below. Each of the three dimensions of the colloidal quantum dots are nanoscale so as to achieve the desired intraband transition described above. This includes 100 nm or less, 50 nm or less, 25 nm or less, or in a range of from 1 nm to 25 nm, 3 nm to 20 nm, or 5 nm to 15 nm. The three dimensions may be of similar magnitude to each other such that the colloidal quantum dots may be spherical in shape and the overall size may refer to a diameter of the colloidal quantum dots. However, “spherical” does not mean perfectly spherical, e.g., as the colloidal quantum dots may be faceted. The colloidal quantum dots may assume other shapes (e.g., cubic, pyramidal, tetrahedral, ovoid). For non-spherical shapes, the overall size may be taken as the largest cross-sectional dimension of the colloidal quantum dots, which may be within any of the dimensions described above. The overall sizes/dimensions in this paragraph may refer to an average value for the collection of colloidal quantum dots in the active region. As noted above, the overall size of the colloidal quantum dots also affects the electronic structure of the colloidal quantum dots, including the energy of the intraband transition, the overall size may be selected accordingly.

When a shell semiconductor is used, the shell may be characterized by a shell thickness. The shell thickness may be selected to achieve any of the functions described above with respect to selection of the shell semiconductor. In embodiments, the shell thickness is that corresponding to a monolayer of the shell semiconductor or multiple monolayers (e.g., 3, 5, 7, 10) of the shell semiconductor. The shell thicknesses in this paragraph may refer to an average value for the collection of core-shell quantum dots in the active region.

As noted above, the quantum dots of the active regions are colloidal. The term “colloidal” is used in reference to the growth of the quantum dots by reacting semiconductor precursor compounds (e.g., metal salts, organometallic compounds) in solution under appropriate conditions. The term “colloidal” is also used in reference to the relatively small size and monodispersity of the resulting quantum dots and their capability of being homogeneously dispersed into an appropriate solvent(s), thereby forming a colloid. The synthesis of colloidal quantum dots may be carried out as described in the Examples, below. Such synthesis may be used to form any of the colloidal quantum dots described herein. Colloidal quantum dots are distinguished from quantum dots formed using other techniques, including epitaxial quantum dots formed using an epitaxial growth technique (e.g., molecular beam epitaxy or metal-organic chemical vapor deposition).

The colloidal quantum dots of the active region are doped, e.g., n-doped. Doping may be carried out as described in the Examples, below. Doped colloidal quantum dots may be characterized by a doping level n, which may refer to the occupancy of the lower energy quantum state (e.g., 1Sₑ) involved in the intraband transition. The doping technique described in the Examples below allows for control of the doping level n and FTIR spectroscopy may be used to quantify the value of n. An n of 0 indicates zero occupancy of the lower energy quantum state, i.e., undoped, while n of 2 indicates occupancy of the colloidal quantum dot by 2 electrons, e.g. a filled 1Sₑ state. Desirably, the colloidal quantum dots are partially doped, i.e., n is in a range of from greater than 0 to less than 2. This includes from greater than 0.01 to less than 2, or greater than 0.02 to less than 2. In embodiments, n is in a range of from greater than 0.01 to 1.5, from greater than 0.02 to 1.5, from 0.1 to 1.5, from 0.1 to 1, from 0.1 to 0.7, from 0.1 to 0.5, or from 0.5 to 0.7. The doping level n in this paragraph may refer to an average value for the collection of colloidal quantum dots in the active region.

The colloidal quantum dots of the active region may be characterized by a carrier (e.g., electron) mobility. As described in Example 3, below, the degree of carrier mobility depends upon the chemical composition of the colloidal quantum dots and may be further tuned via solution ligand exchange. In general, colloidal quantum dots exhibiting a wide range of carrier mobilities may be used, e.g., from 0.0001 cm²V⁻¹s⁻¹ to 10 cm²V⁻¹s⁻¹ at room temperature. However, in embodiments, colloidal quantum dots having relatively high electron mobilities are used, including electron mobilities of greater than 0.3 cm²V⁻¹s⁻¹, greater than 0.5 cm²V⁻¹s⁻¹, greater than 0.7 cm²V⁻¹s⁻¹, at least 1 cm²V⁻¹s⁻¹, or at least 1 cm²V⁻¹s⁻¹ at room temperature. Techniques for measuring carrier mobility are described in Example 3, below. Increased carrier mobility may be realized by using colloidal quantum dots composed of a core semiconductor (no shell semiconductor) and appropriate molecular ligands on the surface of the core semiconductor. As discussed in Example 3, although decreased carrier mobility may be useful to increase the efficiency of incoherent emission from the present quantum dot cascade light emitting devices (see Examples 1 and 2), increased carrier mobility may be useful to facilitate coherent emission (i.e., lasing) from the present quantum dot cascade light emitting devices.

The active region of the present quantum dot cascade light emitting devices is in the form of a film of the colloidal quantum dots. Within the film, individual colloidal quantum dots are close-packed. Such an active region is formed by depositing a colloidal solution of colloidal quantum dots on a desired substrate. Various deposition techniques may be used, e.g., inkjet deposition, spin coating, blade coating, and drop casting. Illustrative details of the drop casting technique are provided in the Examples, below. By “close-packed,” it is meant that adjacent colloidal quantum dots are in contact with one another such that carriers (e.g. electrons) are able to tunnel from dot to dot. However, the contact is generally only over a portion of the colloidal quantum dot surfaces, e.g., spherical colloidal quantum dots may be in contact over a relatively small area. Thus, within the three-dimensional close-packed structure of the film of the colloidal quantum dots, individual colloidal quantum dots are distinguishable from one another. This is by contrast to continuous, highly crystalline epitaxial semiconductor structures, including epitaxial quantum dots, which exhibit distinct but continuous layers. The relative non-uniformity in the physical structure of the active region of the present devices as compared to epitaxial devices further underscores the unexpected finding that the present devices achieve quantum cascade light emission.

In further contrast to epitaxial quantum dot structures, (which are necessarily deposited under ultrahigh vacuum and can only lead to parallel multilayers with some hexagonal order in the plane and with some level of registry along one direction (the vertical growth direction) due to strain propagation), the present colloidal quantum dots films are deposited from a colloidal solution and imaging may be used to confirm the distinct three-dimensional close-packed structure. Moreover, for sufficiently spherical and uniform colloidal quantum dots, the resulting dried films can exhibit three-dimensional extended order, such as a face centered cubic or hexagonal close-packed lattice structure. More complex lattices are possible with binary colloidal solutions.

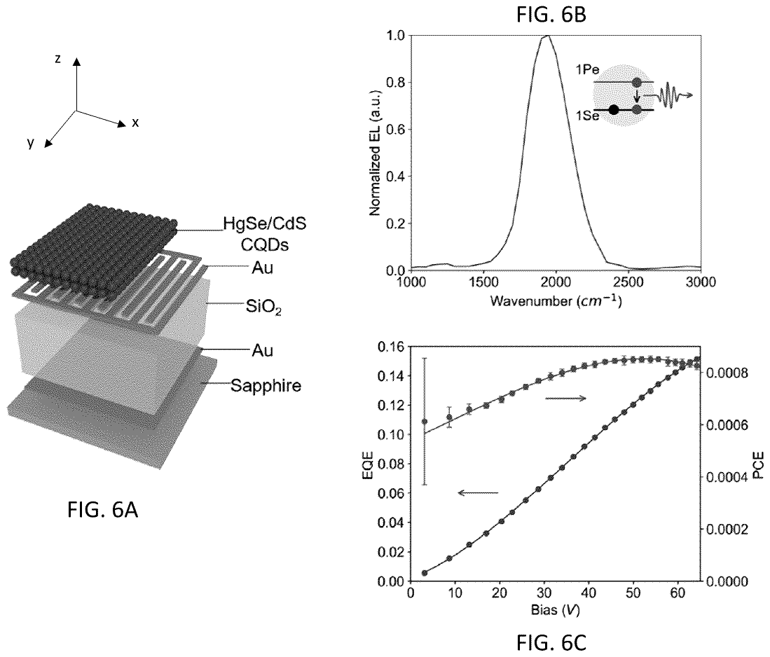

Referring to the illustrative quantum dot cascade device shown in FIG. 1A, current flows through the film of colloidal quantum dots, i.e., the active region, along the z axis. This dimension may be referred to as the channel length of the active region. The illustrative device of FIG. 1A has a vertical architecture and the channel length corresponds to the thickness of the film, which in turn corresponds to the number of stacked colloidal quantum dots (as measured along the z axis). Thus, the channel length/film thickness depends upon the overall size of the colloidal quantum dots and the number of stacked quantum dots. In general, the present quantum dot cascade devices may include any desired number of stacked colloidal quantum dots, e.g., 10s, 100s, 1000s, or 10,000s of stacked colloidal quantum dots (as measured along the channel length). Similarly, the present quantum dot cascade devices may be fabricated with any desired channel length. However, in embodiments, illustrative channel lengths may include those that are no more than 0.05 μm or in a range of from 0.05 μm to 2 μm. This includes from 0.1 μm to 1.8 μm and from 0.2 μm to 1.5 μm. Short channel lengths are useful for providing large optical enhancements. However, larger channel lengths may also be used. In embodiments, illustrative channel lengths include those in a range of from 2 μm to 10 μm. This includes from 3 μm to 9 μm, and from 4 μm to 8 μm. A planar architecture is useful for achieving larger channel lengths. In a planar architecture, such as that shown in FIG. 6A, current flows through the film of colloidal quantum dots, but along the x axis.

In embodiments, the active region consists of the colloidal quantum dots (which may be partially doped core-shell quantum dots as described above). Any of the core semiconductors and shell semiconductors described herein may be used in such embodiments. Such embodiments can, but do not necessarily, preclude the presence of compounds or species used in the synthesis of the core-shell quantum dots and the fabrication of the action region, e.g., ligands used in the colloidal synthesis, dopants used in the doping process.

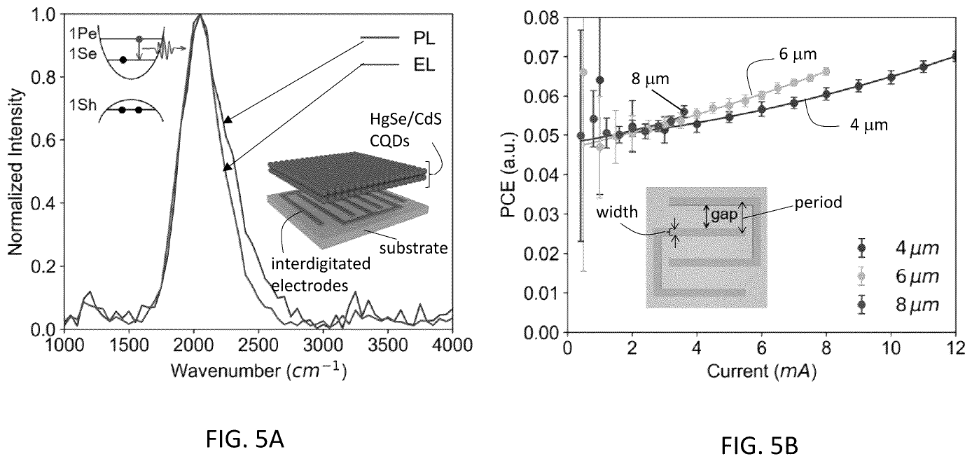

As noted above, the present quantum cascade quantum dot light emitting devices further comprise a pair of electrodes configured to apply an electrical bias across the active region. The particular materials and arrangement of such electrodes are not limited, provided these selections allow application of the electrical bias to drive carriers (e.g., electrons) through the active region. Illustrative materials include transparent conductors and metals. Regarding arrangement, the pair of electrodes may be positioned as a sandwich around the active region (e.g., see FIG. 1A), with the emitted light going through the electrodes. However, as illustrated in FIGS. 5A and 6A and described in Example 2, below, alternative arrangements may be used in which the pair of electrodes is part of a plurality of electrodes positioned within a plane and on one side of the active region. An alternative such arrangement includes the use of planar interdigitated electrodes. As shown in FIG. 5B, such electrodes may be characterized by a width w′, gap g, and period P.

The present quantum cascade quantum dot light emitting devices may comprise other material layers and components. For example, carrier injection layers and carrier blocking layers may be used, e.g., to facilitate injection of electrons into the active region and block electron transport through the valence energy band of the core semiconductor of the colloidal quantum dots, respectively. However, regarding carrier injection layers, generally the present devices would not include both an electron injection layer and a hole injection layer since the cascade excitation of the intraband transition relies on a single carrier type (electron or hole). Adhesion layers may be used, e.g., to facilitate adhesion of the colloidal quantum dots to an underlying layer. Optical enhancement layers can be used to maximize the light extraction, such as a Ge layer. Composition, morphology, and the arrangement of such material layers may be selected on the basis of these respective functions as well as the particular configuration of the active region. As another example, optical components configured to direct light emitted from the present devices may be used, e.g., optical microstructures. The device may be fabricated on an underlying substrate, e.g., sapphire or a flexible substrate such as a polymeric sheet. Other components that may be used include spacer layers, back reflector layers, and nanoantennae. These additional possible components are further described below with respect to FIGS. 6A, 8A, 9A, and 12. In at least some embodiments, however, the quantum dot cascade light emitting devices do not comprise carbon nanotubes.

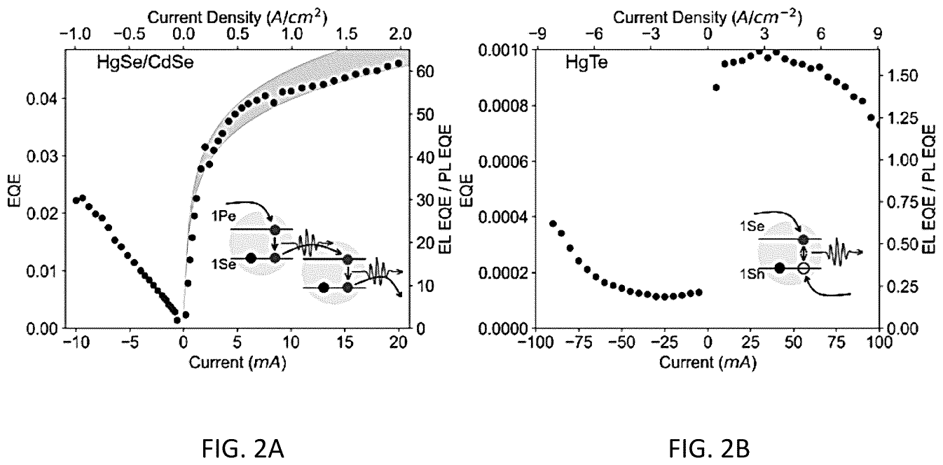

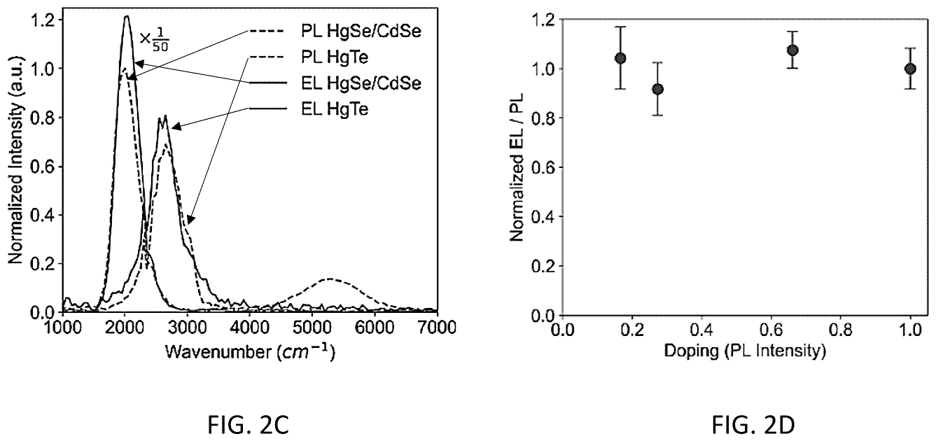

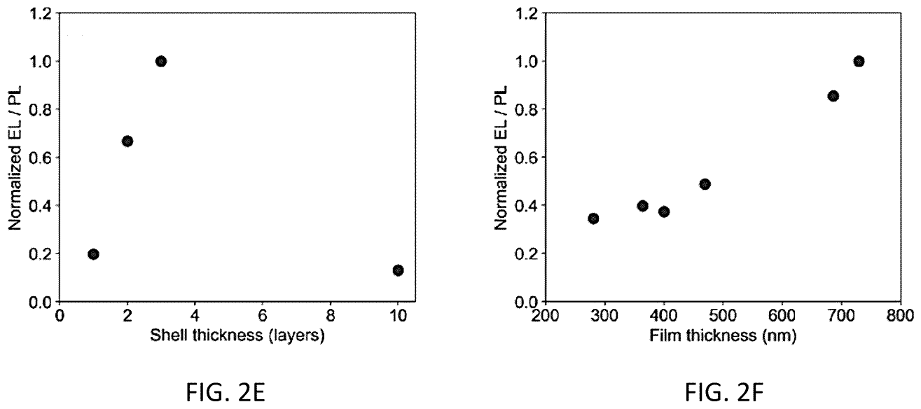

An illustrative embodiment of a quantum dot cascade light emitting is shown in FIG. 1A. Moving from bottom to top, the device includes a sapphire substrate, an indium tin oxide (ITO) bottom electrode, a zinc oxide (ZnO) electron injection layer, an adhesion layer (not shown), an active region in the form of a film of close-packed, partially doped, colloidal HgSe (core)/CdSe (shell) quantum dots, a polyvinylcarbazole (PVK) electron blocking layer, a germanium (Ge) optical enhancement layer, and a gold/platinum (Au/Pt) top electrode. As demonstrated in Example 1, below, this device was found to emit light via a quantum cascade process upon application of sufficient electrical bias, as evidenced by its electrooptical properties, e.g., greater electroluminescence per electron as compared to photoluminescence per photon (e.g., 60-fold, see FIGS. 2A-2C.) Fabrication and testing of this device are described in detail in the Example 1 below. The embodiment shown in FIG. 1A is not intended to be limiting and variations may be used according to the description provided herein. In addition, although the device of FIG. 1A includes a single active region, multiple active regions, e.g., an array of separated active regions on an underlying substrate may be used.

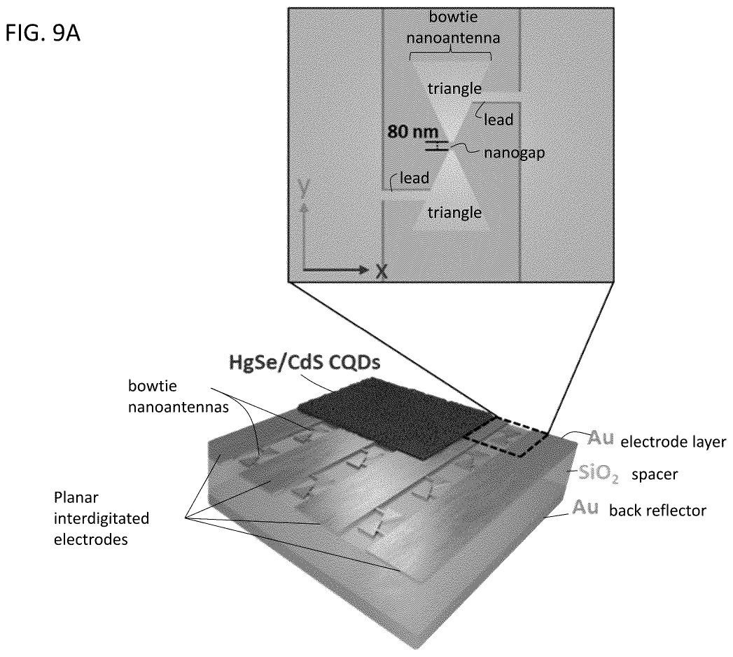

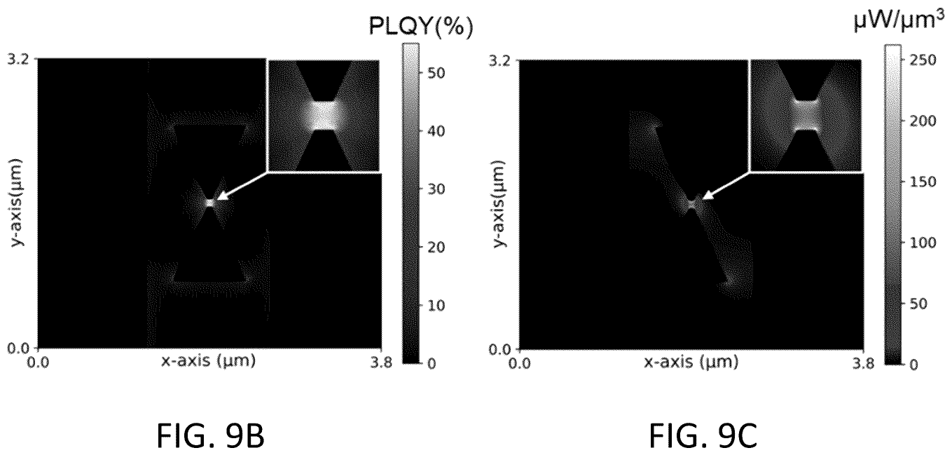

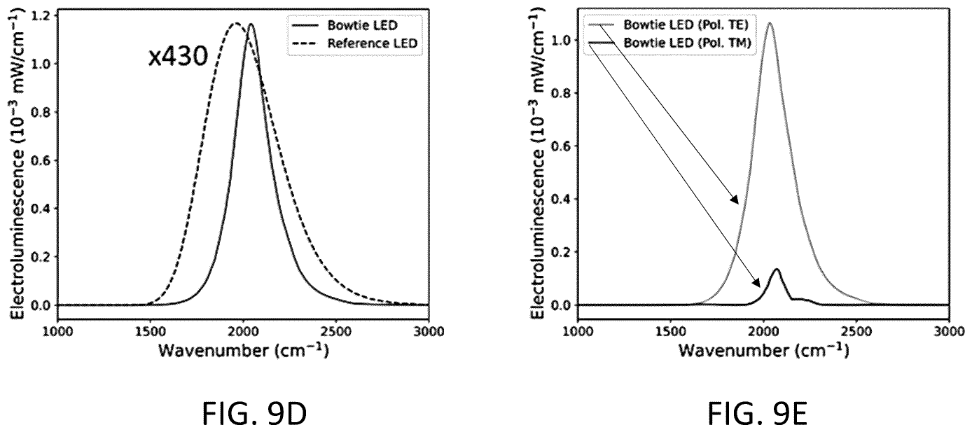

Other illustrative embodiments of quantum dot cascade light emitting devices are shown in FIGS. 5A, 6A, 7A, 8A (showing a portion of a device), 9A and 12 (showing the geometric parameters of the metallic structure of the device of FIG. 9A). Regarding FIG. 6A, moving from bottom to top, the device includes a sapphire substrate, a back reflector layer (Au), a spacer layer (SiO₂), a planar interdigitated electrode layer (Au), and an active region in the form of a film of close-packed, partially doped, colloidal HgSe (core)/CdS (shell) quantum dots. As demonstrated in Example 2, below, this device was also found to emit light via a quantum cascade process upon application of sufficient electrical bias, as evidenced by its electrooptical properties. Fabrication and testing of this device are described in detail in Example 2 below. Example 2 further demonstrates improved optical properties are achieved by using planar interdigitated electrodes and the spacer layer. Moreover, the configuration of these components may be selected to ensure that a desired optical mode supported by the device is resonant with the wavelength of light emitted from the colloidal quantum dots, i.e., the intraband transition. This may be accomplished by selecting an appropriate thickness of the spacer layer and period of the planar interdigitated electrodes.

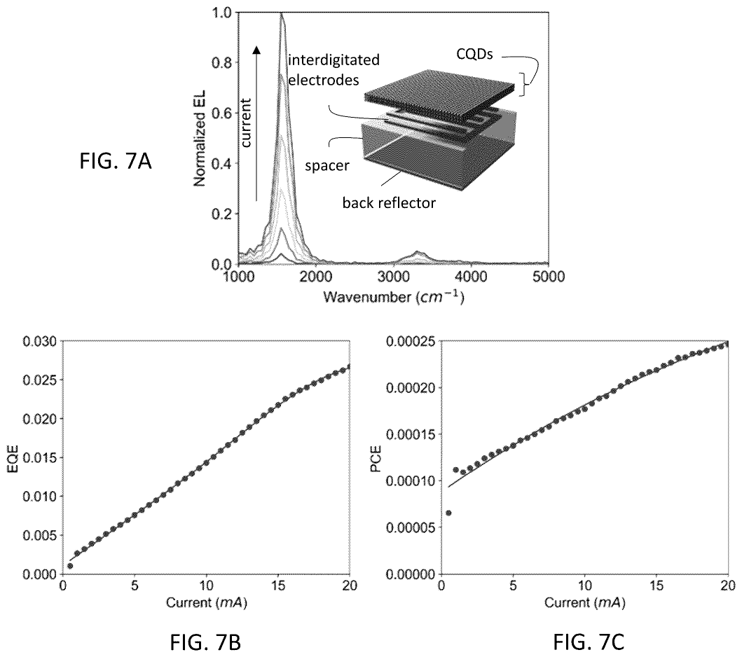

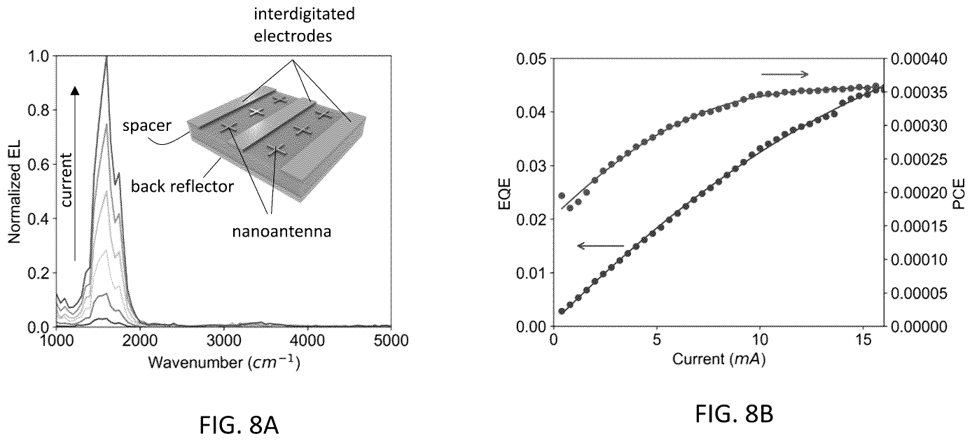

Regarding FIG. 8A, nanoantennas (in this embodiment, in the shape of crosses) are shown added between gaps defined in the planar interdigitated electrodes of the device otherwise shown in FIG. 7A. Fabrication and testing of this device are described in detail in Example 3, below. Example 3 further demonstrates that the nanoantenna and their particular configuration (e.g., shape, dimensions, placement) greatly improves EL EQE (compare FIG. 8B (nanoantenna) to FIG. 7B (no nanoantenna)).

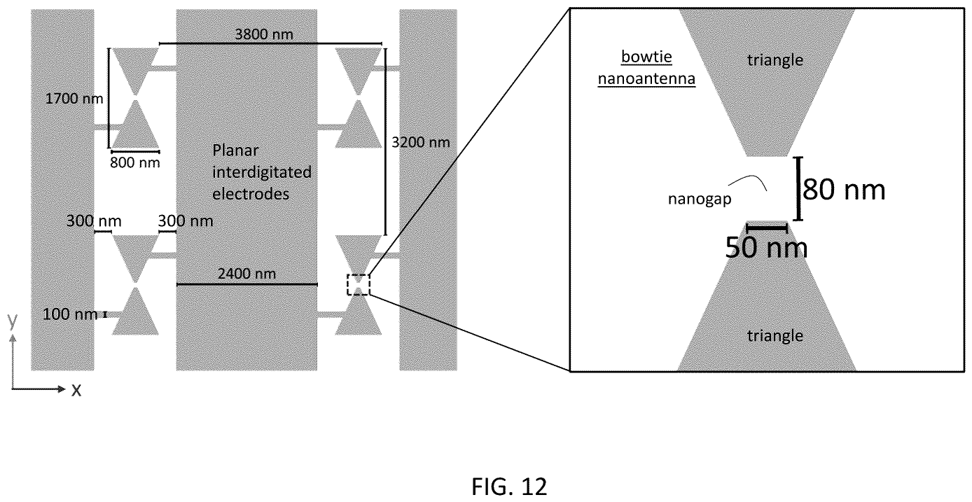

Regarding FIG. 9A, a different type of nanoantennas (in this embodiment, in the shape of bowties) are shown added between gaps defined in the planar interdigitated electrodes of the device. The geometric parameters of the metallic structure of the device (i.e., the planar interdigitated electrodes and nanoantennas) are shown in greater detail in FIG. 12. Each bowtie antenna is configured as a pair of oppositely oriented triangles, each triangle positioned to define a gap therebetween (i.e., a bowtie nanogap). As illustrated in FIG. 9A, multiple colloidal quantum dots of the overlying active layer are positioned within each bowtie nanogap. Each triangle of each bowtie antenna is in electrical communication with an element of the planar interdigitated electrodes via a lead. Fabrication and testing of this device are described in detail in Example 4, below. Example 4 further demonstrates that the nanoantenna and their particular configuration (e.g., shape, dimensions, placement, periodicity) greatly improves EL EQE (compare “bowtie LED” in FIG. 9D (nanoantenna) to “reference LED” (no nanoantenna)). Regarding the configuration, Example 4 further describes the use of optical and electrical simulations to determine the optimal configuration of nanoantennas, as well as the optimal configuration of the leads and of the planar interdigitated electrodes. Moreover, as demonstrated in Example 4, below, the device with the bowtie nanoantennas exhibits over a 270-fold improvement in PCE as compared to the reference device without the nanoantennas.

The present quantum dot cascade light emitting devices may be characterized by various electrooptical properties, e.g., wavelength of the light emission and the electroluminescence external quantum efficiency (EL EQE). The wavelength of the light emission generally refers to the wavelength at the peak of an electroluminescence spectrum as measured from the device (see FIGS. 1F, 5A, 6B, 7A, 8A, 10B). The EL EQE for the device may be measured using techniques as described in the Examples, below (see FIG. 2A, 6C, 7B, 8B, 10E). As described above, particular values of these electrooptical properties may be achieved, e.g., by adjusting the configuration of the active region of the devices according to the guidance provided above. However, in embodiments, the wavelength is in a range of from 1 μm to 20 μm. This includes from 2 μm to 12 μm, from 2 μm to 10 μm, from 3 μm to 10 μm, from 3 μm to 6 μm, and from 4 μm to 7 μm. In illustrative embodiments, the EL EQE at room temperature, light emission wavelength at 6.25 μm, and a current density of 2 A/cm², is at least 5%, at least 7%, at least 9%, at least 11%, at least 13%, or at least 15%. As noted above and described in detail in the Examples, below, these values of EL EQE are surprisingly high given that a film of colloidal quantum dots would have been expected to provide far too many non-radiative pathways to allow for quantum cascade emission. This result, as well as much greater EL EQE (e.g., 60 times greater) as compared to photoluminescence (PL) EQE is clear evidence of quantum cascade light emission from the present devices. (See FIGS. 2A-2C; see also FIG. 2F.) Thus, the present devices may be characterized as exhibiting a greater EL EQE as compared to PL EQE (each measured using techniques as described in the Example, below). The specific ratio of EL EQE to PL EQE depends upon the ratio of channel length to size of the colloidal quantum dots. However, in embodiments, the present devices may exhibit greater EL EQE than PL EQE, including at least 5 times greater, at least 10 times greater, at least 20 times greater, at least 30 times greater, at least 40 times greater, or at least 50 times greater. Further regarding EL EQE, this parameter is limited by the overall bias, the number of colloidal quantum dots that the current passes through, the PL efficiency of the dots, and the light extraction efficiency. For a device of having a channel length of 1 μm, corresponding to 100 dots, at electrical bias of 25 V, there are 100 possible excitations per electron. With a PL efficiency of 100%, and perfect extraction, the EL EQE would be 10,000%. Thus, improvements in PL will allow for even higher EL EQEs as compared to those demonstrated in Examples 1-4.

The present disclosure also provides methods of using any of the quantum dot cascade light emitting devices described herein to generate light. A basic embodiment of such a method comprises applying an electrical bias to the active region to induce light emission therefrom. The electrical bias must be sufficient to drive the carriers through the active region and achieve the quantum cascade effect. The selected electrical bias depends upon the channel length as well as size and composition of the colloidal quantum dots. Otherwise, the electrical bias is be selected to achieve any of the EL EQE values described above. In embodiments, the electrical bias is at least 10 V, at least 15 V, at least 20 V, at least 50 V, or 100 V. This includes a range in between any of these values and from 10 V to 30 V. These values are larger than would be used in interband devices since for such devices higher voltage is not required simply results in wasted excess energy. In embodiments, however, smaller electrical biases may be used.

It is noted that the property of light emission distinguishes the present devices from devices configured to absorb light (e.g., photodetectors). In embodiments, the light emission from the present devices is incoherent light emission (i.e., as distinguished from coherent, laser light emission). Moreover, as described throughout the present application, the light emission from the present devices originates from intraband transitions. This distinguishes the present devices from devices configured to emit light from interband transitions, which involves the recombination of electrons and holes to generate light. For example, the device of Zhao, Y., et al. Nature Electronics 3.10 (2020): 612-621 is a device configured to emit light via interband transitions. Further regarding interband devices, such devices may make use of component(s)/materials(s) to provide a source(s) of both carrier types, i.e., electrons and holes, in order to facilitate the interband transitions. Some other interband devices (including those of Zhao et al.) use a rapidly switching polarity to generate light from the interband transitions, where space charge of one carrier is built up under one polarity and rapidly removed by recombination when the reverse polarity is applied. In embodiments of the present quantum dot cascade light emitting devices, such component(s)/material(s) are excluded and light emission is obtained using constant current (DC current). Thus, at least in embodiments, the present quantum dot cascade light emitting devices do not comprise both a source of electrons and a source of holes and do not rely on AC currents to operate. These embodiments do not exclude the colloidal quantum dots themselves as the semiconducting materials from which the dots are composed are capable of containing both electrons and holes, but rather these embodiments refer to the exclusion of additional component(s)/material(s) providing both a source of electrons and a source of holes.

### EXAMPLES

### Example 1

Data and information referenced as “not shown” in this Example may be found in U.S. provisional patent application No. 63/472,738 that was filed Jun. 13, 2023, which is hereby incorporated by reference.

### INTRODUCTION

Electroluminescence at 5 microns wavelength was obtained using the 1Sₑ-1Pₑ intraband transition of core/shell HgSe/CdSe colloidal quantum dots (CQD). With a 3 monolayer CdSe shell thickness, the electroluminescence efficiency was about 50-fold larger than in a device that uses the interband transition of 10 nm core-only (no semiconductor shell), undoped mid-infrared HgTe colloidal quantum dots. Surprisingly, the measured electroluminescence quantum efficiency was up to 4.5% at 2 A/cm² which is similar to commercial epitaxial cascade quantum well light emitting diodes. The unexpectedly high emission efficiency and the electrical characteristics establish that the present light emitting devices emit light via a quantum cascade process where the electrons, driven by the bias across the device, repeatedly tunnel into 1Pₑ and relax to 1Sₑ as they hop from quantum dot to quantum dot. This is believed to be the first report of quantum cascade light emission from a device based on colloidal quantum dots.

### EXPERIMENTAL

### ZnO Nanoparticle Synthesis

ZnO nanoparticles were synthesized as follows. 0.296 g zinc acetate dehydrate and 12.5 mL methanol were added to a 50 ml three-neck flask. The solution was heated to 60° C. under vigorous stirring. 0.152 g potassium hydroxide (KOH) was dissolved in 6.5 mL methanol. The KOH solution was added to the zinc acetate solution dropwise in about 5 min. The solution was kept at 60° C. for 2 h.

The solution changed to whitish after 1-1.5 h. The heating mantle was removed after 2 h. The solution cooled down to room temperature naturally. The solution was centrifuged. The supernatant was discarded, and the precipitate was cleaned with methanol three times. The precipitate was then dissolved in 4 mL chloroform/methanol 1/1 solution. The solution was stored at ambient conditions.

HgSe CdSe Solution Cleaning and n-Doping

80 μL HgSe/CdSe solution was diluted by 0.5 mL tetrachloroethylene (TCE). Ethanol was added dropwise until the solution became turbid. The solution was centrifuged. The supernatant was discarded, and the precipitate was dissolved in 1 mL TCE. Cadmium acetate hydrate was added to the solution to n-dope the sample. Excess cadmium acetate hydrate did not dissolve. The solution was heated to boiling for 1 min. After cooling down, 80 μL 0.1 M didodecyldimethylammonium bromide solution in isopropanol was added to help redispersion. Ethanol was then added to precipitate the quantum dots. The solution was centrifuged. The supernatant was discarded, and the precipitate was dissolved in 0.5 mL TCE for fabrication.

### LED Fabrication

Sapphire substrates were cut into 12.5 mm×12.5 mm pieces and cleaned by sonication in 2% Alconox solution, acetone, and isopropanol for 15 min, respectively. 40 nm indium tin oxide (ITO) was sputtered over the substrate at 10⁻⁸ Torr. A 4 mm wide strip of tape was manually cut and used to cover the ITO down the middle of the substrate. The substrate was exposed to HCl vapor for 15 s and rinsed with distilled water. The tape mask was then removed, and the remaining ITO was annealed at 300° C. in a quartz tube furnace for 1 h, yielding an electrode with a square resistance of ˜80 Ohm.

The ZnO solution was spin-coated at a speed of 2000 rpm for 30 s. Three layers of ZnO solution were spin-coated in total to achieve the thickness of 100 nm. The substrate was then annealed at 260° C. on a hotplate for 2 min.

2% poly(diallyldimethylammonium chloride) in water solution was dropped to cover the film for 10 s to help quantum dots bind to the surface. The film was rinsed with distilled water and dried with nitrogen. The substrate was heated to 35° C. 2 drops of HgSe/CdSe quantum dots solution were drop cast on the substrate with a glass Pasteur pipet. The solution was lightly swirled to keep covering the substrate before wicking. 5% 1,2-ethanedithiol in IPA solution was dropped to cover the film for 10 s. The film was rinsed with IPA and dried with nitrogen. The procedure was repeated to reach the desired film thickness. The substrate was then annealed at 150° C. on a hotplate for 5 min.

10 mg poly(9-vinylcarbazole) was dissolved in 2 mL chlorobenzene. The solution was spin-coated at a speed of 1600 rpm for 30 s. 200 nm Ge, 15 nm Pt, and 20 nm Au were evaporated at 10⁻⁸ Torr by electron beam through a mask.

### Photoluminescence (PL) Measurements

PL spectra were obtained from the LED samples. Briefly, samples were excited with an 808 nm laser diode modulated by a sine wave at 90 kHz. The signal was collimated by a gold-coated f/2 parabolic mirror and sent through a step-scan Michelson interferometer to a cooled HgCdTe detector. A silicon wafer was placed in front of the detector to filter out the laser. The detector output was sent through a lock-in amplifier. The interferometer was controlled by a step motor and scanned to give 50 cm⁻¹ resolution spectra after Fourier transformation.

### Electroluminescence (EL) Measurements

LED samples were tested using a Keithley Model 6221 AC and DC Current Source. A sine wave modulated at 9 kHz with 0 mA to a peak current was applied to the sample. The EL spectra were measured using the same set up as the PL spectra. The peak voltage was measured by viewing the voltage change on oscilloscope and taking the maximum value. The fabricated devices are DC devices as the light emission intensity follows the absolute value of the current, rather than the derivative of the current as in AC devices.

### External Quantum Efficiency (EQE) Determination

The PL EQE was determined as follows. Briefly, an absolute PL EQE measurement was made for an undoped HgSe/CdSe sample on film using a Spectralon integrating sphere and a PbSe detector. The PL spectrum of this sample was taken. The measured spectrum was normalized by the ratio of a measured and calculated blackbody photon flux. The PL EQE per unit spectrum area ratio was then calculated. The PL EQE of other samples were determined by taking a spectrum, normalizing to blackbody photon flux and absorbed laser power, and calculating using the ratio described above. The EL EQE was determined in the same way using the injected electron number instead of absorbed photon number.

Additional experimental information is provided in “Additional Information,” below.

### Results

A schematic of the quantum cascade quantum dot device formed in this Example is shown in FIG. 1A. It consists of a sapphire substrate with a 40 nm ITO layer as one electrode coated by a 60 nm ZnO layer by spin coating which was subsequently annealed. The energy alignment diagram of the device is shown in FIG. 1B. The ˜500 nm colloidal quantum dot (CQD) film was made by multiple drop-casting and ligand exchange. FIGS. 1C and 1D show the transmission electron microscope (TEM) images of the HgSe CQDs cores and the core/shell CQDs. The CdSe shell was about 3 monolayers thick. On top of the CQD layer, a 10 nm PVK layer was spin coated. Then, a 200 nm Ge semi-insulating layer was evaporated. Finally, the top electrode was evaporated through a shadow mask, with 15 nm Pt followed by 20 nm Au. Each device area was measured by optical microscopy, and was found to be about 1 mm². The light was extracted from the ITO side. A cross-section scanning electron microscope (SEM) of the device is shown in FIG. 1E.

Electroluminescence was excited by a current source producing a sine wave from 0 mA to a certain peak current at 9 kHz, with the frequency being limited by the current source. The emitted light was sent through a step-scan Michelson interferometer and collected by an MCT detector. The signal was then analyzed by a lock-in amplifier. FIG. 1F shows the EL spectra at different currents. The emission was characteristic of the intraband transition 1Sₑ-1Pₑ of the HgSe cores. It peaked around 5 microns with a FWHM of about 440 cm⁻¹. The peak center and the FWHM are were obtained (data not shown). The peak position blue-shifted by about 50 cm⁻¹ at small current and did not change much at larger current, while the FWHM increased a little with current, from 420 cm⁻¹ to 450 cm⁻¹. The peak current, peak voltage, and peak radiance are shown in FIG. 1G. The device worked with a large voltage, with +20 V at +5 mA and +32 V at +20 mA. The device was not Ohmic, with the voltage increasing fast for small current and more slowly for larger current. The device also showed a weak rectification with a smaller voltage for the same current in forward bias, defined as the positive bias on the PVK. The EL signal was also stronger in forward bias and it increased with current, with a peak radiance of 75 W/sr/m² at +20 mA. The power conversion efficiency (PCE) of the device is shown in FIG. 1H. The PCE was 0.07% at +2 mA and average electrical power 16 mW and dropped only to 0.05% at +20 mA and average electrical power 320 mW. The device stability, tested using a +10 mA sine wave current at 9 kHz, is shown in FIG. 1I. The EL signal dropped 15% over 2 h and the voltage increased from 30 V to 40 V.

The EL EQE is shown in FIG. 2A. The EL EQE increased fast at small current and slowly at large current, reaching about 4.5% at +20 mA. The device PL EQE was recorded using an 808 nm laser modulated by a sine wave at 90 kHz. In contrast to the EL, the PL showed some interband emission in addition to the intraband emission. The PL intraband EQE was determined to be 0.075%. Thus, the EL EQE was up to 60 times larger than the PL EQE.

### DISCUSSION

### Cascade Mechanism

The EL performance of the present intraband HgSe/CdSe CDQ LED was vastly improved as compared an interband HgTe pn CQD LED, which achieved an EQE of only 3.4×10⁻⁴ and PCE of 5.0×10⁻⁵ for an average electrical power of 80 mW. (See Shen, X.; et al. ACS nano 2022, 16 (5), 7301-7308.) FIG. 2B further shows that the present intraband HgSe/CdSe CDQ LED outperforms a similarly structured device using interband HgTe CQDs. Yet, the present intraband HgSe/CdSe CDQ LED showed about the same PL efficiency as the HgTe interband device. The significantly brighter EL than PL is consistent with light emission from the present intraband HgSe/CdSe CDQ LED via a cascade mechanism, where one injected carrier gives rise to multiple emissions as it falls down the device from quantum dot to quantum dot. Given the 0.25 eV energy gap between 1Pₑ and 1Sₑ states, the working voltage of up to 20 V across ˜50-100 dot layers gives plenty of potential energy for electrons to tunnel many times from the 1Sₑ state of one quantum dot into the 1Pₑ state of another quantum dot downstream and relax each time with some radiative probability. Although this cascade mechanism has been demonstrated from the quantum wells of epitaxial multilayer semiconductor structures, the present Example is believed to be the first demonstration of cascade light emission from layers of colloidal quantum dots. Moreover, in view of the extreme sensitivity of cascade light emission on the composition, thickness, and arrangement of quantum wells and barriers of epitaxial multilayer semiconductor structures, the existence and efficiency of the cascade light emission from the present intraband HgSe/CdSe CDQ LED was entirely unexpected. For example, prior to the present demonstration, the colloidal quantum dots films would have been thought to provide far too many non-radiative pathways through the device to achieve cascade light emission. However, the sparse intraband level structure that arises from a sufficiently dispersive conduction band is beneficial to the efficient electrical injection of electrons from level 1 of one quantum dot to level 2 of another, and thus, contrary to conventional wisdom, the inventors have determined there is no need for the very precise layer engineering required for epitaxial devices.

### Transport Model

In forward bias, the IV curve of the present intraband HgSe/CdSe CDQ LED can be approximated by J∝Vⁿ with n˜2.8 after a small turn-on voltage. Such power law exists in space-charge limited transport with traps, and it has been invoked in visible emitting CdSe/ZnS CQD LEDs. In these visible emitting devices, the reported values of n are 5-9. The Mott-Gurney model gives an exponent n=2, while for an exponential tail of trap energies of the form

$$exp ( \frac{- E}{{kT}_{c}} ) ,$$

the Mark-Helfrich model gives

$$n = \frac{{T}_{c}}{T} + 1 .$$

However, the space charge model only applies if the material is sufficiently insulating, and this is not necessarily the case with infrared gap CQD films. Indeed, the values obtained for doping and mobility of the present HgSe/CdSe CQD film (see “Additional Information” below) show that the space charge limited current would be 3 orders of magnitude too small from 10V to 1V bias.

An alternative transport model is a field-driven hopping transport, such as the Poole-Frenkel model, which prescribes a conductivity given by

$${σ}_{o} ( T ) exp ( \frac{q}{kT} \sqrt{\frac{qE}{π {ε}_{QD}}} )$$

where E is a uniform electric field across the material. ε_{QD} is the permittivity of the CQD film taken to be 4ε₀. Combining a 350Ω series resistance and a 2500Ω shunt resistance, the Poole-Frenkel model gave a very good fit of the IV curve in forward bias as shown in FIG. 1G.

In analogy to the case of single electron-hole recombination, the EL EQE for the cascade device is expressed as

$${η}_{EL} = {η}_{rec} \cdot ( \frac{eV}{Eg} ) \cdot {η}_{rad} \cdot {η}_{ext .} \frac{eV}{Eg}$$

is the maximum possible cascade gain, such that for every voltage increment equal to the energy gap (0.25 eV), there would be an electron transferring from 1Sₑ to 1Pₑ. η_{rec} is a downward correction to that maximum possible gain which is effectively the probability of the electron being injected in the 1Pₑ state. η_{rad} is the probability of 1Pₑ-1Sₑ emission, ηₑₓₜ is the photon extraction probability. Assuming the same ηₑₓₜ for EL and PL, the PL EQE is η_{PL}=η_{rad}·ηₑₓₜ. The EL radiance is calculated as

$$Radiance = \frac{I \cdot {η}_{E L}}{π \cdot A} = \frac{η P L}{π \cdot A} \cdot {η}_{r e c} \cdot I ( \frac{eV}{{E}_{g}} ) ,$$

where π is the solid angle for a Lambertian radiator, A is the device area, I and V are the current and voltage through the junction. The radiance vs current is bracketed using η_{rec} between 0.68 and 0.60. This corresponds to a photon emitted for every 0.36-0.41 V additional bias. The EQE and PCE calculated using the same parameters are shown in FIGS. 2A and 1H. The interpretation of these results is that there is a surprisingly good transfer of the electrons from 1Sₑ of one dot to the 1Pₑ state of the dot down the line as the electrons cascade down from the cathode to the anode. As noted above, this is a very unexpected result given the simplicity and imperfection of the CQD films as compared to the elaborately band engineered quantum wells of epitaxial multilayer semiconductor structures.

### Device Structure

Further experiments were done to explore the effect of the device structure as well as the effects of core-shell quantum dot doping, shell thickness, and CQD film (active region) thickness. The details are presented in “Additional Information,” below. Regarding the device structure, it was found that removing either the ZnO or PVK reduced the emission efficiency by several fold. The Ge layer was added to provide a ¼ wave distance between the metal electrode and the middle of the CQD film, and this improved the emission efficiency 2-3-fold. The Pt/Au electrode improved the lifetime of the devices compared to just Au.

Regarding the doping of the CQDs, the doping level was controlled by the amount of cadmium acetate added in a final reheat of the CQD solution. FIG. 2D shows that, as the intraband PL increased by a factor of 10 across samples with stronger doping, the EL followed the same trend such that the ratio of EL to PL was similar for all the samples. This indicates that the intraband EL was also proportional to the number of doped dots. This may be due to that fact that when an electron tunnels from 1Sₑ of one dot to a dot downstream, the branching ratio to 1Pₑ is higher if there is already an electron blocking 1Sₑ because of the combination of electron-electron repulsion, statistical benefits, and drive potential.

Regarding shell thickness, FIG. 2E shows that the EL was maximized at 3 monolayers of CdSe. This is believed to be due to a compromise between emission efficiency, tunneling, and doping. While intraband PL increased with shell thickness, the thick shell samples (10 monolayers of CdSe) were much harder to n-dope than the thinner shell samples (1, 2, 3 monolayers).

Regarding active region thickness, FIG. 2F shows that increasing the thickness of the active region (i.e., increasing the number of individual CQD layers), increases the EL/PL ratio. This is consistent with the need for a higher voltage to produce the same current, and is further evidence that the light emission is via the cascade mechanism.

In summary, this Example demonstrates intraband electroluminescence via a quantum cascade process at 5 μm from n-doped core/shell HgSe/CdSe CQDs in a simple device architecture. The device showed a remarkable EQE of 4.5% at 2 A/cm² while the power efficiency was 0.05%. These values are well within range of those obtained from much more complicated, sensitive, and expensive epitaxial quantum well cascade LEDs. Moreover, the epitaxial structures generally have currents on the order of kA/cm², while the present quantum cascade colloidal quantum dot devices operate at low currents on the order of A/cm². The current is determined by the mobility of carriers. As mobility increases from 0.001 cm²/Vs to 1 cm²/Vs, currents can reach kA/cm² and may lead to population inversion required for lasing.

The present Example indicates that the efficiency of the emission at each cascade is close to the photoluminescence QY of the transition. The demonstrated devices have a small photoluminescence QY of 10⁻³, but the power conversion efficiency already reaches 0.05% as LEDs. Therefore, as the PL efficiency of the quantum dot films improves, higher power conversion efficiency will be achieved, greatly exceeding the efficiency of solid-state devices based on quantum wells which is in the 1% range at best.

### Additional Information

### HgSe CdSe Synthesis

Chemicals: Mercury chloride (HgCl₂) was purchased from Alfa Aesar (99.999%, #10808) and Sigma-Aldrich (99.5%, #215465). Cadmium acetate dihydrate (Cd(OAc)₂, 98%, #20901), oleylamine (OAm, 70%, #909831), tetrachloroethylene (TCE, 99%, #443786), and ethanedithiol (EdT, 98%, #02390) were purchased from Sigma-Aldrich. Bis(trimethylsilyl) selenide ((TMS)₂Sₑ, 97%, #SIB1871.0) was purchased from Gelest. Isopropanol (IPA, 99.9%, #A451-4) was purchased from Fisher. (Di-n-dodecyl) dimethylammonium bromide (DDAB, 98%, #B22839) was purchased from Alfa Aesar. (TMS)₂Sₑ was stored in a N₂ glovebox, while the rest were stored in ambient conditions. All syntheses were performed using the same bottle of oleylamine; variability in HgSe size and colloidal stability was observed when different batches of the chemical were used.

### Precursors and Stock Solutions

0.2M (TMS)₂Sₑ solution: The solution was prepared by adding 100 μL (TMS)₂Sₑ (0.4 mmol) to 1.9 mL oleylamine in a N₂ glovebox.

0.2M Cd(OAc)₂ solution: 78 mg of Cd(OAc)₂. 2H₂O (0.3 mmol) was added to 1.5 mL oleylamine in a test tube, and heated till the solids dissolved. The solution remained clear as it cooled to room temperature.

### Thin Shell HgSe CdSe/QD Synthesis

The synthesis was performed according to the following protocol to yield ˜20 mg of HgSe cores. The protocol could be scaled 4× with no noticeable differences. HgSe core size was ˜4.8 nm.

HgCl₂ (0.1 mmol, 27 mg) was added to a 3-neck flask with 5 mL oleylamine. The flask was equipped with a stir bar, rubber sleeve stoppers with a thermocouple attached, and connected to a Schlenk line manifold. Three vacuum (p˜1 torr)-Argon flush cycles were performed at room temperature, and the flask was heated at 100° C. for ˜30-60 minutes. The temperature was then set to 90° C. 0.5 mL of 0.2 M (TMS)₂Sₑ solution was injected swiftly into the flask, which led to the solution instantly turning black, and a stopwatch was started. At 15 seconds, a calculated volume of 0.2 M Cd(OAc)₂ solution (“0Cd”) was injected over a period of ˜15 seconds. Subsequent half-cycles were performed till “3Cd”, with a 2-minute reaction time for Sₑ-cycles and 5-minute reaction time for Cd-cycles. This led to QDs with a diameter ˜7 nm (denoted HgSe/3CdSe).

Concentration of the thin shell HgSe/CdSe stock solution was determined by measuring the absorbance at 700 nm. Absorption at this wavelength should be dominated by the HgSe cores, with negligible shell absorption. The concentration of HgSe was determined using the cross-section of HgSe as 3.5×10⁻¹⁸ cm² per Hg atom (calculated from the reported cross-section at 415 nm and the measured HgSe absorption spectrum)₂. The typical reaction yield was ˜20-25 mg of HgSe.

The stock solution was transferred into a glass vial and stored in a freezer. The solution could be stored for several months with no observable change.

### Spectra at Different Current

The EL spectra were taken at different peak currents (data not shown). The emission peak was then fitted to a Gaussian function and the peak center and FWHM were obtained (data not shown).

### HgSe CdSe Film Preparation and Conductivity

The HgSe/CdSe CQDs synthesis and characterization were carried out as follows. The CQD film was made by multiple drop-casting and ligand exchange. Afterwards, the sample was heated to 150° C. for 5 min as this was found to improve the intraband emission at the expense of the interband emission. Such heating increases n-doping, possibly by removing adsorbed water, and it may also drive off excess molecular moieties that could quench the emission.

The conductivity of the CQD film was measured with similar films on interdigitated electrodes of Au (data not shown). The electrodes included 25 pairs of interdigitated evaporated gold fingers with gap 10 μm and length 1 mm. The thickness of the CQD film was about 100 nm. The IV curve was nearly Ohmic, giving a conductivity of 1.5×10⁻⁷ S/cm. With the volume of the nanocrystal from TEM size determination, and assuming a random close packing, a doping density of ˜3×10¹⁷ cm⁻³, and a mobility of 3×10⁻⁶ cm²/Vs was estimated, which is 3-4 orders of magnitude lower than the mobility of core-only HgSe films.

### Conductivity and Optical Enhancement of Ge Layer

The IV curve of 100 nm Ge layer evaporated on interdigitated electrodes was obtained (data not shown). The electrodes included 17 pairs of interdigitated evaporated gold fingers with gap 20 μm and length 1 mm. A room temperature conductivity of ˜0.7×10⁻³ S/cm was calculated. Therefore, the Ge layer contributed only 2.6Ω to the series resistance which is negligible compared to the ITO.

Transmittance and reflection spectra of 100 nm Ge on sapphire were obtained (data not shown). The refractive index and extinction coefficient of Ge were fitted to the transmittance and reflection using the Forouhi-Bloomer model and transfer matrix method. The fitted results were also obtained (data not shown). The extinction coefficient was nearly zero in mid-infrared with less than 1% absorption for 200 nm thick films.

The Ge layer improved light extraction by distancing the CQD film from the metal. Using the index of refraction of the 200 nm Ge layer (˜4) and the index of the 500 nm CQD film (˜2), the ¼ wave of 5 microns was in the middle of the CQD film. The absorbance of the CQD film in the device is simulated by transfer matrix method. The forward and backward wave intensity for each interface was calculated and used to obtain the local absorption density through each layer. The absorption through the CQD film was then integrated. The layers used include: Sapphire, ITO (40 nm), ZnO (60 nm), CQD (500 nm), PVK (10 nm), Ge (200 nm), Back reflector. The absorption in 5 μm was enhanced after including a 200 nm Ge layer, and therefore will benefit the outcoupling as well. Devices with the Ge layer were about 2-3 times as bright as devices without.

### Pt Au Top Electrode

The top electrode used a first evaporation of Pt followed by Au. Pt served as an adhesion layer to restrict the diffusion of Au during evaporation. It was also found to provide a more robust electrode compared to just an Au layer, where the gold film was removed in serpentine patterns over tens of microns scales after a few minutes of operation. The Pt layer alleviated this problem, suggesting that Pt provides a barrier layer to Au electromigration.

ZnO and PVK layer

ZnO and PVK were used to inject electrons into and block electrons from the CQD film. Given the weak rectification as shown in FIG. 1G, it was initially unclear if any asymmetry was needed. It should also be difficult to accurately match the 1Pₑ and 1Sₑ levels. Therefore, an ITO-Ge-CQD-Ge-Au structure was tested. This device emitted less than 1/10 signal as compared to the ZnO-PVK device at the same current. The device has nearly Ohmic electrical transport with a resistance of 500Ω which is primarily attributed to the CQDs film. This suggests that devices benefit from an asymmetry in the carrier injection, although such asymmetry is not a requirement. Deviating from the ITO-ZnO-CQD-PVK-Au stack, it was found that by removing the ZnO layer, the emission was significantly lower. The ZnO layer is less absorbing in the mid-IR than ITO and it is naturally n-doped in ambient conditions, so that its Fermi level is close to the HgSe 1Sₑ states. It is therefore a good electron injection layer for HgSe. Keeping the ZnO but removing the PVK also lowered the emission intensity. The valence band of PVK is significantly lower than the 1Sₑ state of HgSe. As a result, it is likely that the electrons flow preferentially from the cathode ZnO to the anode PVK. In addition, devices with no ZnO layer or no PVK layer show much worse stability and were easily shorted by applying a current. The ZnO and PVK layers therefore also help to protect the CQD film from directly contacting the electrodes.

### Influence of Doping

The doping of CQDs was controlled by the amount of cadmium acetate added in a final reheat of the CQD solution. In PL measurements, the intraband emission increased (data not shown) while interband emission decreased (data not shown) as doping increases while the 808 nm excitation is absorbed equally by doped and undoped dots. However, the devices gave only intraband EL emission (data not shown). This indicates that the EL devices cannot inject holes in the HgSe valence band.

As the intraband PL increased by a factor of 10 across samples with stronger doping, the EL followed the same trend such that the ratio of EL to PL was similar for all the samples (data not shown).

### Influence of Shell Thickness

The shell affects the doping of the sample and the electrical conductivity. The PL increased with shell thickness. The thin shell samples (1, 2, 3 monolayers) were easily n-doped and showed only intraband EL, while the thick shell QDs (10 monolayers) could not be fully n-doped and gave both intraband and interband EL. The EL spectra of thick shell samples were sensitive to the current (data not shown). Only intraband was observed at small current and interband was observed at large current. The intraband EL to PL ratio as well as the interband EL to PL ratio of thick shell samples were obtained (data not shown). The ratio increases with shell thickness first and drops when the shell goes thicker.

The cascade gain relies on the films being resistive enough so that a large bias can be applied, and this is another role of the shell thickness because the CQD film becomes more resistive with thicker shells. For the same current, a thicker shell requires a larger voltage drop across two dots and this increases the probability for a 1Sₑ electron to tunnel into a 1Pₑ state. Thus, as the shell is grown thicker the intraband EL should increase. However, at the thickest shells, which are the least conductive, the voltage drops across dots needed to sustain a similar current keeps increasing, to the extent that electrons in the valence band may start to move and give interband emission.

### Influence of QDs Film Thickness

Devices were made with different CQDs film thickness. The PL increased with film thickness, possibly because of more laser absorption and the better extraction efficiency (data not shown). The EL for the same current also increased with film thickness. Moreover, the EL to PL ratio increased with film thickness, since a higher voltage is needed to produce the same current, supporting the cascade mechanism.

### Real Time Signal

The device was driven by the current source with a current from 0 mA to 20 mA modulated by a sine wave at 9 kHz. The EL signal from the MCT was directly seen using an oscilloscope coupled by AC (data not shown). The modulation frequency was limited by the current source.

### EL-Input Power

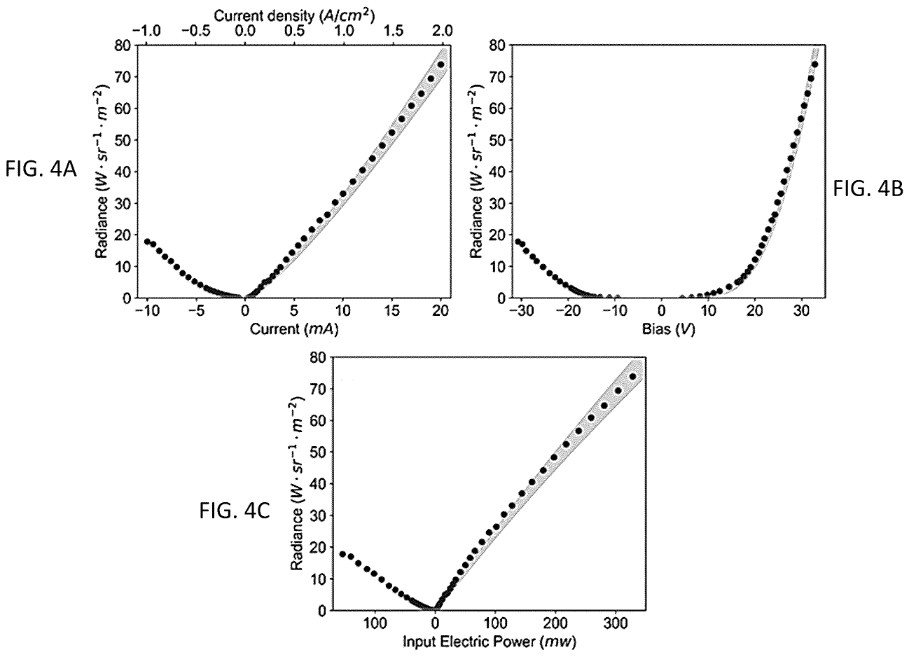

The EL intensity vs input power was plotted and is shown in FIGS. 4A-4C. For conventional LEDs, EL is driven by current. EL intensity grows linearly with current, with possible efficiency droop at large current. By contrast, in the present cascade device, EL is driven by both current and bias. The EL intensity grows nonlinearly with either current (FIG. 4A) and bias (FIG. 4B), and show most linearity on a plot vs current × bias (power) (FIG. 4C). For quantum cascade emission, the EL quantum efficiency does not vary much with increasing channel length as long as the current is maintained the same with a corresponding bias increase. This is different from electron-hole recombination light emitting diodes (interband devices) for which increasing channel length leads to rapid drop of efficiency that cannot be compensated by increasing the bias.

### EL—Current in a Small Range

A plot of the EL intensity vs current in a small range was obtained (data not shown). EL could be detected at current of 0.2 mA and bias 4.40 V, and grew smoothly with current. No clear threshold to the cascade effect was observed. Further measurement is limited by the sensitivity of the setup.

### Example 2

In this Example, additional experiments similar to those described in Example 1, above, were carried out. Specifically, 5 μm electroluminescence in a planar device was realized using a film of core/shell HgSe/CdS colloidal quantum dots deposited on interdigitated electrodes. Experimental details are provided in “Additional Information” below. The efficiency of the planar device was comparable to the vertical device of Example 1, but fabrication is simplified. Since the emission is from the intraband transition of the HgSe cores, the planar device is driven by a single-charge carrier type, and this allows identical electrodes of arbitrary design, without additional charge transport layers. Studies of the effects of doping and temperature were done using an added bottom gate electrode (data not shown). The planar structure eliminates the requirement of the infrared transparency of the electrodes. With a back reflector, a dielectric spacer, and optimized electrode spacing and periodicity, a device emitting at 5 μm achieved a remarkable external electron-to-photon conversion of 15% and a power conversion efficiency of 0.085%.

The schematic of one of the fabricated planar devices is shown in the inset of FIG. 5A. Interdigitated electrodes were made on a sapphire substrate by photolithography and evaporation. Partially n-doped HgSe/CdS QDs (CQDs) were prepared by colloidal atomic layer deposition (cALD). The thin shell HgSe/CdS dots showed comparable intraband photoluminescence (PL) quantum yield (QY) to the HgSe/CdSe dots synthesized in Example 1, but the cALD method allows the adjustment of the PLQY, doping, and mobility by the number of shell layers and the surface chemistry. The QDs solution was drop cast on the substrate and crosslinked by ethanedithiol (EdT). Multiple layers were drop cast made until the desired thickness was reached. The PL spectrum of the device was measured using 808-nm diode laser excitation. As shown in FIG. 5A, a peak at about 2,000 cm⁻¹ (5 μm) was observed, characteristic of the 1Sₑ-1Pₑ intraband transition of the HgSe cores. Also shown in FIG. 5A, when the device was then driven by a current source for EL measurements, a similar intraband emission peak was observed. Different from interband emission where a balanced injection of electrons and holes is required, the results show that electron-only intraband emission is possible without any device asymmetry.

Next, to improve the emission in the collected direction, the interdigitated electrodes were evaporated on top of a 600-nm SiO₂ spacer on a back reflector. This structure, together with the ˜300-nm dots film, forms a quarter-wave cavity. FIG. 5B shows the PCE with different electrode patterns in which the electrode width is 2 μm, but the gap sizes vary from 4 to 8 μm. Despite the different current-voltage curves, all of them show similar PCE. Thus, devices with larger gaps require larger drive voltages and emit more light, but the constant power efficiency is further evidence of the cascade mechanism.

Additional experiments were conducted to evaluate the optimal doping level for the HgSe/CdS CQDs (data not shown). The results indicated that the optimal doping level was less than 1 electron/dot. Specifically, at 80 K, the optimal doping level was found to be about 07 electron/dot and a room temperature, the optimal doping level was found to be about 0.5 electron/dot.

By contrast to quantum well cascade devices, it was realized that the planar architecture using the present lower-index CQD films are able to facilitate photon extraction as well as the incorporation of optical enhancement structures. Thus, devices were made with two types of structures, each using a HgSe/CdS CQDs film with ˜1 electron/dot. The reference structure used a ˜300-nm thick HgSe/CdS CQDs film on top of 50-nm gold interdigitated electrodes with 2-μm width and 4-μm gaps on bare sapphire. The optimized, enhanced device is shown in FIG. 6A and includes a 50-nm Au back reflector on sapphire, 1.2-μm SiO₂ spacer, and 50-nm gold interdigitated electrodes with 1.7-μm-width and 1.7-μm gaps.

Both devices were tested using a current source modulated by a sine wave at 2 kHz. The EL spectra show a clean peak at ˜1,950 cm⁻¹. The EL spectrum of the enhanced device is shown in FIG. 6A. When the EL spectra were normalized to the input electric power, the EL intensity was ˜10× larger for the enhanced device compared to the reference device. The peak voltage reached ˜60 V for the small gap device, after which the electrodes as well as the QDs film started to break down (data not shown). The current-voltage curve was slightly nonlinear (data not shown). The resistance was ˜30Ω for the reference device and 6.5Ω for the enhanced device. Benefiting from both the larger current and the better efficiency, the enhanced device reached a peak radiance of ˜120 W sr⁻¹ m⁻² assuming Lambertian emission, 40× larger than the reference device (data not shown). The EQEs of both devices increase nearly linearly with voltage. As shown in FIG. 6C, the EQE of the enhanced device reached ˜15% (FIG. 4E). Also shown in FIG. 6C, the PCE increased slowly with voltage at small biases and droops a bit at the highest voltages, but it is a remarkably small variation overall. The peak PCE of the enhanced device reached 0.085%.

The performance of the enhanced planar device is already better than the intraband HgSe/CdSe QDs device in a vertical ZnO/QDs/PVK stack as described in Example 1, above. This Example shows that the lack of charge transport layers in the planar device does not destroy the transport properties; instead, it enables better extraction efficiency, resulting in better efficiency and brightness.

### Additional Information

### Chemicals

The chemicals used were mercury (II) chloride (HgCl₂, Sigma-Aldrich, R99.5%, cata-log no. 215465, 100 g), oleylamine (OAm, Sigma-Aldrich, 70%, catalog no. 07805, 500 g), selenourea (Thermo Fisher, R98%, 5 g), toluene (Thermo Fisher, catalog no. T290, 4 L), ethanol (Decon, catalog no. 2701, 1 gal), formamide (FA, Sigma-Aldrich, R99.0%, catalog no. F7503, 1 L), ammonium sulfide solution ((NH₄)₂S, Sigma-Aldrich, 40-48 wt % in H₂O, catalog no. 515809, 100 mL), cadmium acetate hydrate (Cd(OAc)₂, Sigma-Aldrich, R99.99%, catalog no. 229490, 25 g), (di-n-do-decyl)dimethylammonium bromide (DDAB, Thermo Fisher, R98%, 10 g), 2-propanol (IPA, Thermo Fisher, catalog no. A451-4L), tetrachloroethylene (TCE, Sigma-Aldrich, R99.0%, catalog no. 443786, 2.5 L), chlorobenzene (Sigma-Aldrich, R99.5%, catalog no. 23570, 2.5 L), butyl acetate (Sigma-Aldrich, R99.5%, catalog no. 402842, 1 L), 1,2-Ethanedithiol (EdT, Thermo Fisher, R98%, 100 g), Cy-top (AGC, catalog no. CTL-809M, 0.1 kg), and CT-Solv1 80 (AGC, 0.1 kg).

### HgSe C′QDs Synthesis

HgSe cores are synthesized as follows. HgCl₂ (0.13 mmol, 35 mg) was added to a 20-mL glass vial. OAm (4 mL) was added. The vial was placed in a glove box and heated to 100° C. for ˜30 min. The temperature was then set at 80° C. Selenourea (0.5 mL 0.2 M) in OAm solution was injected and reacted for 30 min. The reaction was quenched by adding toluene (8 mL). The solution was precipitated by ethanol. The solution was then centrifuged, and the precipitate was redissolved in toluene (10 mL). The stock solution was stable in ambient conditions for months.

### HgSe CdS CODs Synthesis

The HgSe/CdS core/shell QDs were synthesized by cALD. Stock solution (1 mL), OAm (100 mL), and FA (1.5 mL) were added to a test tube. Two phase was formed. (NH₄)₂S (60 mL) was added and stirred for 2 min (HgSe-S). The FA phase was discarded. The toluene phase was washed with FA (1 mL) three times. After this, FA (1.5 mL) and Cd(OAc)₂ (90 mL 0.1 M) in FA solution were added and stirred for 2 min (HgSe-S-Cd, HgSe/1CdS). The FA phase was removed, and the toluene phase was washed with FA (1 mL) three times.

After growing the desired number of CdS layers, the toluene phase was precipitated with DDAB (150 mL 0.1 M) in IPA solution and ethanol. The solution was centrifuged, and the precipitate was redissolved in TCE. The cleaning process was repeated again, and the precipitate was redispersed in chlorobenzene/butyl acetate solution (0.5 mL 1/10) for film preparation.

Growing more cycles of CdS was found to improve PLQY and thermal stability, as well as reduce n-doping. HgSe with 1, 2, and 3 monolayers of CdS shell were stable at ˜100° C., 120° C., and 150° C., respectively. Ending the cALD process with the S cycle produced more intrinsic dots.

### Substrates Preparation

The field effect transistor (FET) substrates were prepared using a doped silicon wafer with 300 nm thermal oxide. The electrodes were made by 10 nm Ti, 50 nm Au, and 5 nm Pt using e-beam evaporation. The area was defined by photolithography.

The substrates with back reflector and spacer were prepared on 2-in sapphire wafers. The top-emitted device does not impose specific substrate requirements. Sapphire was used due to its transparency in mid-IR and good thermal conductivity. The back reflector was made of 5 nm Ti, 50 nm Au, 5 nm Ti using e-beam evaporation. The area was defined by photolithography. The SiO₂ spacer was deposited on the whole wafer by high-density plasma chemical vapor deposition (HDPCVD). The electrodes were made of 5 nm Ti and 50 nm Au using e-beam evaporation, with the area defined by photolithography.

For photolithography, the wafer was placed in a vacuum bake oven at 110° C. and primed with hexamethyldisilazane (HMDS). An ˜1-mm AZ MiR 703 photoresist was spin-coated on top and baked at 95° C. for 1 min. The pattern was exposed to a 375-nm laser at a 120-mJ cm⁻² dose using Heidelberg MLA150. The wafer was then baked at 115° C. for 1 min. The wafer ws immersed in AZ300 MIF developer with agitation for 1 min and rinsed with water.

### HgSe CdS CODs Film Preparation

The substrate was heated to 40° C. HgSe/CdS solution was prepared as described above. One drop of solution was drop casted onto the substrate with a glass Pasteur pipette. The substrate was lightly rotated to keep the solution covering the substrate. The excess solution was wicked away. EdT (5%) in IPA solution was dropped to cover the film for 10 s. The film was rinsed with IPA and dried with nitrogen. The procedure was repeated to reach the desired film thickness. Annealing the film at ˜100° C. for 5 min between layers was found to improve device stability. For FET measurements and low-temperature measurements, a thin film (<100 nm) of Cytop was spin-coated to protect the film from the environment.

PL and EL measurements and the EQE determination were carried out similar to those described in Example 1.

### Example 3

In this Example, additional experiments similar to those described in Example 1, above, were carried out. Specifically, intraband cascade electroluminescence was demonstrated with weakly n-doped HgTe colloidal quantum dots deposited on interdigitated electrodes. The device showed an emission peak at 1600 cm⁻¹ (6.25 μm) at room temperature, with an external quantum efficiency of 2.7% and a power conversion efficiency of 0.025%. The performance was further enhanced with gold antennas, reaching a quantum efficiency of 4.4%, and a power efficiency of 0.036%.

In order to explore the intraband electroluminescence of HgTe CQDs, devices were made with films of moderate electron mobility (0.01 cm² V⁻¹ s⁻¹) as well as with higher electron mobility (1 cm² V⁻¹ s⁻¹).

Low mobility devices using solid state ligand exchange with ethanedithiol: HgTe CQDs were synthesized as described below and drop casted to form a film. The dots were spherical with a diameter of 7.8 nm. The dots were slightly n-doped at ˜0.1 electron/dot. The film was treated with a solution of HgCl₂ and crosslinked with EdT. The HgCl₂ treatment may passivate the surface and enhance the PL of CQDs. The absorption and PL spectra of the dots film were measured (data not shown). The absorption was measured for a film on a ZnSe prism for attenuated total internal reflection. The interband edge rose between 2600 cm⁻¹ and 3600 cm⁻¹ with the “cutoff” defined as the half point on the edge, around 3100 cm⁻¹. The film showed weaker intraband absorption, corresponding to the 1Sₑ to 1Pₑ transition between 1500 cm⁻¹ and 2000 cm⁻¹, and the relative intensity indicated a weak occupation of the 1Sₑ state. The PL was measured for a film deposited on an aluminum polished plate and was excited by an 808 nm pump laser. The interband PL was from 3500 cm⁻¹ to 2200 cm⁻¹, with about a full width at half maximum of about 600 cm⁻¹ and a peak around 2800 cm⁻¹, to the red of the CH vibration modes. The intraband PL was also broad, from 1500 cm⁻¹ to 2000 cm⁻¹, and overlapped with the tail of the interband PL.

A thin film (150 nm) of dots was then fabricated on a metal-insulator-metal (MIM) substrate to test the EL. As shown in FIG. 7A, the MIM substrate included a back reflector, a 630 nm Si spacer, and top interdigitated electrodes with 0.6 μm width and 2.4 μm period. The spacer thickness and the electrode configuration were optimized to improve light extraction at 1600 cm⁻¹ and 3200 cm⁻¹ (data not shown) The PL and EL spectra were measured with the substrate (data not shown). Both interband and intraband appear in the PL spectrum, and they are both much narrowed, occurring mostly at the photonic resonances of the substrate. The interband PL, although mostly red of the photonic resonance, is still stronger than the intraband. The intraband emission peaks at 1600 cm⁻¹, with a FWHM of 200 cm⁻¹. The EL was excited using a current source. The EL intraband emission overlapped well with the PL intraband emission, while the EL interband emission was much weaker.

The intraband EL intensity and radiance increased with larger driving currents as well as the driving voltage. With a current of 20 mA, the voltage reached 30 V, and the radiance reached 34 W sr⁻¹ m⁻² assuming Lambertian emission. As shown in FIG. 7B, the electron to photon external quantum efficiency (EQE) of the device increased fast with the driving current, showing a nearly linear dependence. As shown in FIG. 7C, the power conversion efficiency (PCE) grew more slowly with driving current. At 20 mA, the EQE reached 2.7%, and the PCE reached 0.025%. The fast rise of EQE with current and the increasing PCE with larger currents are characteristics of the cascade emission mechanism. Under the large biases, cascade emission results wherein each electron can be injected into the 1Pₑ state multiple times as it travels through the quantum dot film, resulting in a higher EQE and a stable efficiency at large driving powers.

The performance of the device was demonstrably improved by including an array of plasmonic nanoantennas (herein, gold crosses) in gaps defined by the interdigitated electrodes (see inset in FIG. 8A). The improved substrate features the same back reflector and 630 nm silicon spacer as the grating substrate (FIG. 7A) but the interdigitated electrodes are modified to fit the nanoantenna's within the conductive channels of the device. The electrodes have 2 μm width and 6 μm periodicity. The cross antennas have arms with 2 μm length and 0.2 μm width. Only one period of the nanoantenna array can fit within the channel in the direction perpendicular to the electrodes. In the direction parallel to the electrodes the channel is filled with nanoantennas with 4 μm periodicity. This structure is then covered with a 200 nm film of HgTe CQDs.

The device has larger resistance because of the larger electrode gap. It displays a similar behavior as the grating device presented previously, with EQE and PCE increasing with driving current but with improved performance. Specifically, with a current of 16 mA, the radiance was 45 W sr⁻¹ m⁻², EQE reached 4.4%, and PCE reached 0.036%. This is due to the light-matter coupling provided by the nanoantenna array plasmonic resonance.

Considering a working bias of 35 V, electrode gaps of 2.4 μm, CQDs of 7.8 nm, and an electron mobility of 0.02 cm² V⁻¹ s⁻¹, the hopping time between two dots is estimated at about 300 ps. This is longer than the relaxation lifetime of the 1Pₑ state, which is estimated to be about 100 ps from the 10⁻³ quantum yield, and this prevents population inversion.

The device then made use of HgTe dots subjected to solution ligand exchange by transfer to a polar DMF solvent which reduces the dot-to-dot distance and increases the mobility. Compared to the low-mobility CQD preparation used for the device of FIG. 7A, the solution ligand exchanged CQDs exhibit mobilities of about 100× larger, reaching 1.6 cm² V⁻¹ s⁻¹ for electrons and 0.2 cm² V⁻¹ s⁻¹ for holes.

The voltage and the radiance were observed to increase with the driving current (data not shown). The EQE slowly increased with the current, while the PCE decreased (data not shown). At 30 mA current, the voltage was 37 V, EQE was 0.38%, and PCE was 0.0029%. Although the current and voltage are similar to the device based on low mobility dots, EQE and PCE are about 10× smaller for the device based on high mobility dots. The device based on high mobility dots included 166 pairs of electrodes with a period of 3 μm, which covers a 1 mm² area. Using a 10 nm dots film, the device area was 3.3×10⁻⁵ cm⁻². Thus, the 30 mA driving current gives a large current density of 0.9 kA cm⁻².

Despite the lower EL efficiencies for the device based on high mobility dots, the large current and fast electron injection from 1Sₑ to 1Pₑ between neighboring dots facilitates population inversion and would thus help reach lasing. Indeed, examination using a simple rate equation model shows that the device based on high mobility dots exhibiting high current supports population inversion in favor of stimulated emission. Replacement of the MIM substrate with dielectric structures will reduce optical losses and facilitate lasing.

### Example 4

### INTRODUCTION

This Example provides a novel efficient solution-processable electroluminescent source emitting at 5 microns that was based on integrating the quantum cascade intraband electroluminescence of HgSe/CdS colloidal quantum dots with resonant bowtie antennas. The bowtie provided the electrodes and the cavity for Purcell enhancement, funneling the electrical power to the nanogap where the emission was highly enhanced. Numerical simulations included the losses in the metal and suggested that the external emission efficiency could be up to 50% for a dipole emitter aligned across the nanogap. The electrical to optical power conversion efficiency could reach 10%, assuming ideally orientated dipole emitters. Experimentally, the devices exhibited strong polarized intraband electroluminescence, with the best power conversion efficiency exceeding 5%, and a 270-fold increase over reference structures without the bowtie nanogap. The emission turned on and off in less than 20 ns, confirming its origin from electroluminescence.

### EXPERIMENTAL

### Methods

### Chemicals:

Mercury chloride (HgCl₂, Sigma-Aldrich, 100 g), Oleylamine (OAm, Sigma-Aldrich, 70%), Selenourea (Thermo Fisher, ≥98%, 5 g), Ammonium Sulfide ((NH₄)₂S, Sigma-Aldrich, 40-48 wt % in H₂O, 100 mL), Cadmium acetate dihydrate (Cd(OAc)₂, Sigma-Aldrich, ≥99.99%, 25 g), (Di-n-dodecyl)dimethylammonium bromide (DDAB, Thermo Fisher, ≥98%, 10 g), 1,2-Ethanedithiol (EdT, Thermo Fisher, ≥98%, 100 g), Formamide (FA, Sigma-Aldrich, ≥99.0%, 1 L), Toluene (Thermo Fisher, 4 L), Methanol (MeOH, Thermo Fisher, 4 L), Tetrachloroethylene (TCE, Sigma-Aldrich, ≥99.0%, 2.5 L), Ethanol (EtOH, Decon, 1 gal),), Isopropanol (IPA, Thermal-Fisher, 4 L).

### Hgse Cqds Synthesis:

HgSe cores were synthesized as follows. 35 mg HgCl₂ (0.13 mmol) was added to a 20-mL glass vial. 4 mL OAm was added. The vial was placed in a glovebox and heated to 100° C. for ˜40 min. The temperature was then lowered to 90° C. 0.5 mL 0.2 M Selenourea in OAm solution was quickly injected and reacted for 30 min. The reaction was quenched by adding 8 mL toluene. The solution was transferred out of the glovebox. The solution was precipitated by EtOH, centrifuged, and the precipitate was redissolved in 10 mL toluene. The stock solution was stable in ambient conditions for months.

### HgSe/CdS CQDs Synthesis:

The HgSe/CdS core/shell QDs were synthesized by cALD as follows. 1 mL stock solution, 100 μL OAm, and 1.5 mL FA were added to a test tube. Two phases were formed. 30 μL (NH₄)₂S was added and stirred for 2 min (HgSe-S). The phase separation was formed with light centrifuge. The FA phase was discarded. The toluene phase was washed with 1 mL FA three times. After this, 1.5 mL FA and 60 μL 0.1 M Cd(OAc)₂ in FA solution were added and stirred for 2 min (HgSe-S-Cd, HgSe/1CdS). The FA phase was removed, and the toluene phase was washed with 1 mL FA three times. Four layers of CdS were grown. The toluene phase was precipitated with MeOH. The solution was centrifuged, and the precipitate was redissolved in TCE. Cadmium acetate dihydrate was added to the solution. The solution was boiled for 1 min. The solid cadmium acetate was removed. The solution was cleaned with MeOH and redispersed in TCE again. The solution was precipitated with 150 μL 0.1 M DDAB in IPA solution and EtOH, and redispersed in TCE for film preparation.

### Simulations:

Electrical transport simulations were conducted using Comsol with the AC/DC Electrical Currents module. The 3D simulated system consisted of the unitary cell of the periodic array composing the structure. Only the gold electrodes, bowtie antenna, and HgSe/CdS CQD film were included, since they were the only electrically conductive elements in the device. The gold conductivity was set to 2×10⁷S/m. The CQD film conductivity was set to 0.1 S/m, calculated from conductance measurements using interdigitated electrodes. Periodic boundary conditions were set to the two opposing boundaries perpendicular to the electrodes. The two opposing boundaries along the electrodes were defined as ground and terminal applying 1 V respectively. Top and bottom boundaries were insulating.

The effect of the bowtie resonance on emission properties of emitters was simulated using the Finite Difference Time Domain solution Lumerical. The 3D simulated system was a 3×3 array of the unitary cell of the structure. While a larger system increases computation time, it was necessary to simulate more than one unitary cell to make the system larger than the wavelength of interest (5 μm) and to account for possible near-field coupling between adjacent antennas. From bottom to top, the layer stack consisted of a 1 μm SiO₂ spacer, 50 nm gold electrodes and antenna, and the 60 nm thick CQD film, 15 μm air layer. The refractive index of gold was found from the literature while the refractive index of SiO₂ was set to 1.4. The real part of the refractive index of HgSe/CdS CQDs was set to 1.6, close to previously reported values. The bottom boundary was set as a perfect electric conductor to act as a back reflector. All the other boundaries were set as perfectly matched layers. A point dipole source was placed at some position in the CQD layer to probe the influence on the resonant structure on the radiative decay rate of emitters.

The spectral power emitted by the dipole in the far field Pᵣ(λ) was recorded using a transmission box enclosing the whole simulated system. The spectral power losses in the metallic structure

$${P}_{nr}^{metal} ( λ )$$

were calculated from the data recorded by an electric field monitor enclosing the metal structure. These quantities were multiplied by a gaussian spectrum with FWHM=500 cm⁻¹ and centered at 5 μm to take into account the gaussian emission spectrum of the CQD film.

$${P}_{r} ( λ ) and {P}_{nr}^{metal} ( λ )$$

depend on the dipole moment, which was set arbitrarily in the simulations. Therefore, the spectral power emitted was also simulated in the far field by the same dipole placed in vacuum

$${P}_{r}^{0} ( λ )$$

to obtain a relative emitted power

$$r {\int }_{λ} {P}_{r} ( λ ) / {\int }_{λ} {P}_{r}^{0} ( λ )$$

and to relative losses

$${\int }_{λ} {P}_{n r}^{metal} ( λ ) / {\int }_{λ} {P}_{r}^{0} ( λ ) .$$

These relative quantities provided a relative radiative decay rate and non-radiative decay rate

$${γ}_{r} / {γ}_{r}^{0} and {γ}_{n r}^{metal} / {γ}_{r}^{0}$$

The dipole was positioned at different positions \vec{r} to map the spatial distribution of these relative decay rates in the volume V of the CQD film. For each position, the dipole orientation was varied along the X, Y and Z axis. For each dipole orientation the corresponding decay rates

$${γ}_{r}^{X , Y , Z} ( \vec{r} ) / {γ}_{r}^{0} and {γ}_{n r}^{metal , X , Y , Z} ( \vec{r} ) / {γ}_{r}^{0}$$

were calculated. In total, 486 dipole positions were simulated, which correspond to ˜150 hours of computation time.

For each dipole orientation X, Y and Z, a map of the PLQY across the device was calculated from the simulated

$${γ}_{r}^{X , Y , Z} ( \vec{r} ) and {γ}_{n r}^{metal , X , Y , Z} ( \vec{r} )$$

as.

$$P L Q {Y}^{X , Y , Z} ( \vec{r} ) = \frac{{γ}_{r}^{X , Y , Z} ( \vec{r} )}{{γ}_{r}^{X , Y , Z} ( \vec{r} ) + {γ}_{n r}^{metal , X , Y , Z} ( \vec{r} ) + {γ}_{n r}^{0}}$$

A relative non-radiative decay rate

$${γ}_{n r}^{0} / {γ}_{r}^{0}$$

was calculated from PLQY measurements realized with a CQD film deposited on an aluminum surface. With measured external PLQY=0.03% and assuming 20% photon extraction efficiency,

$${γ}_{n r}^{0} / {γ}_{r}^{0} \approx 650$$

was obtained. It was assumed that

$${γ}_{n r}^{0}$$

did not depend on the dipole orientation. The PLQY map presented in FIG. 9B was constructed by taking the dipole orientation with the best PLQY at each position \vec{r}.

It was assumed that light exiting the simulations system from the SiO₂ spacer or the CQD film was trapped in the structure and did not contribute to the extracted far field emission. Hence, the extraction efficiency was defined as

$${η}_{e x}^{X , Y , Z} ( \vec{r} , λ )$$

calculated from the power emitted toward far field in the air layer

$${P}_{r}^{X , Y , Z , v a c} ( \vec{r} , λ )$$

and dividing it by ule total emitted power

$${P}_{r}^{X , Y , Z} ( \vec{r} , λ ) .$$

The simulated PCE for the best oriented dipoles was calculated from the maps of simulated decay rates, the map of the extraction efficiency, and the map of the electrical power density Pₑ(\vec{r}) (FIG. 9B) as:

$${PCE}_{Best PLQY} = {\int }_{V} [ \frac{{P}_{e} ( \vec{r} )}{{\int }_{V} {P}_{e} ( \vec{r} ) d \vec{r}} \times {( \frac{{γ}_{r , ex}^{X , Y , Z} ( \vec{r} )}{{γ}_{r}^{X , Y , Z} ( \vec{r} ) + {γ}_{n r}^{metal , X , Y , Z} ( \vec{r} ) + {γ}_{n r}^{0}} )}_{Best PLQY} ] d \vec{r} \qquad ( 1 )$$

where

$${γ}_{r , ex}^{X , Y , Z} ( \vec{r} )$$

is a rate corresponding to radiative decay with emitted photon extracted from the device and is defined relatively to

$${γ}_{r}^{0}$$

as

$${γ}_{r , ex}^{X , Y , Z} ( \vec{r} ) / {γ}_{r}^{0} = {\int }_{λ} {γ}_{r}^{X , Y , Z} ( \vec{r} , λ ) {η}_{ex}^{X , Y , Z} ( \vec{r} , λ ) d λ / {\int }_{λ} {P}_{r}^{0} ( λ ) d λ .$$

At each position \vec{r}, the dipole orientation was set to the orientation giving best PLQY. This calculation gives a simulated PCE=10.5%.

Performing the same calculation considering random dipole orientation at each position \vec{r} gave a simulated PCE=4%, using the following expression:

$${PCE}_{random} = {\int }_{V} [ \frac{{P}_{e} ( \vec{r} )}{{\int }_{V} {P}_{e} ( \vec{r} ) d \vec{r}} \times \frac{1}{3} {\sum }_{X , Y , Z} \frac{{γ}_{r , ex}^{X , Y , Z} ( \vec{r} )}{{γ}_{r , ex}^{X , Y , Z} ( \vec{r} ) + {γ}_{nr}^{metal , X , Y , Z} ( \vec{r} ) + {γ}_{nr}^{0}} ] d \vec{r} \qquad ( 2 )$$

Similar simulations were performed with a different geometry consisting of 1 μm wide interdigitated gold electrodes with 1 μm spacing to simulate the reference device. In this case, the bottom boundary was set as a perfectly matched layer and the SiO₂ spacer was replaced with a 15 μm thick sapphire layer with a refractive index of 1.6. For the reference device, the calculated PCE was 0.04% for randomly orientated dipoles.

The polarized emission intensity spectra of the devices through F/2 optics were calculated from the maps of the decay rates, the electrical power density map Pₑ(\vec{r}), the map of spectral emission intensity in TE or TM polarization, and toward F/2 optics

$${P}_{r , F / 2}^{X , Y , Z , TE / TM} ( \vec{r} , λ ) : {I}_{TE / TM} ( λ ) = {\int }_{V} [ {P}_{e} ( \vec{r} ) \times {( \frac{{γ}_{r , F / 2}^{X , Y , Z , TE / TM} ( \vec{r} , λ )}{{γ}_{r}^{X , Y , Z} ( \vec{r} ) + {γ}_{nr}^{metal , X , Y , Z} ( \vec{r} ) + {γ}_{nr}^{0}} )}_{Best PLQY} ] d \vec{r} \qquad ( 3 )$$

where

$${γ}_{r , F / 2}^{X , Y , Z , TE / TM} ( \vec{r} , λ )$$

is a rate per unit wavelength corresponding to emission of a photon at wavelength λ with TE or TM polarization and extracted by F/2 optics. It was defined relatively to

$${γ}_{r}^{0}$$

as

$${γ}_{r , F / 2}^{X , Y , Z , TE / TM} ( \vec{r} , λ ) / {γ}_{r}^{0} = {P}_{r , F / 2}^{X , Y , Z , TE / TM} ( \vec{r} , λ ) / {\int }_{λ} {P}_{r}^{0} ( λ ) d λ .$$

$${P}_{r , F / 2}^{X , Y , Z , TE / TM} ( \vec{r} , λ )$$

was recorded from the simulations using an electric monitor with size and distance from the substrate set to mimic an F/2 aperture. This equation gives an emission intensity spectrum for best oriented dipoles. This was the calculation used to construct the spectra shown in FIGS. 9D-9E and other data not shown.

The emission intensity was summed over both polarizations to obtain the unpolarized emission spectrum.

### Substrate Fabrication:

The fabrication process began with a 2-in. C-plane sapphire wafer, rinsed in acetone and isopropanol. The wafer was spin-coated with AZ MIR 703 photoresist at 3500 rpm for 45 s and baked for 1 min at 95° C. 800×800 μm squares were patterned using a Heidelberg MLA150 direct-write lithographer (375 nm laser, 120 mJ/cm² dose). After a 1 min post-exposure bake at 115° C., the resist was developed for 1 min in AZ 300 MIF and rinsed with water.

A metal stack of 5 nm Ti/150 nm Au/1 nm Ti was deposited by electron-beam evaporation (Angstrom EvoVac). Lift-off was performed by sonicating the wafer in N-methyl-2-pyrrolidone (NMP) at 80° C. for 10 min, followed by rinsing in NMP, acetone, and IPA. The square gold mirrors acted as back reflectors for the bowtie devices.

A 1 μm SiO₂ layer was deposited over the entire wafer via HDPCVD (Plasma-Therm Apex SLR). Macroscopic contact pads were then defined in a second photolithography step, again using AZ MIR 703 and the Heidelberg MLA150 with identical exposure parameters. After development, 2 nm Ti/50 nm Au was deposited (Angstrom EvoVac) to form the electrical contact pads.

Interdigitated electrodes and bowtie antennas were defined by electron-beam lithography. The wafer was spin-coated with AR-P 6200-09 at 4000 rpm for 45 s, baked at 150° C. for 1 min, and covered with a conductive top layer of AR-PC 5090.02 (2000 rpm, 45 s) baked at 90° C. for 2 min. Patterning was performed with a Raith EBPG5200 (100 kV, 300 μC/cm² dose, 10 nA beam current) with proximity-effect correction to avoid electrical shorts in the nanogaps.

Following exposure, the conductive AR-PC 5090.02 layer was removed by rinsing in water. The e-beam resist was developed in amyl acetate for 1 min and rinsed in IPA. A 2 nm Ti/50 nm Au stack was deposited (Angstrom EvoVac), followed by lift-off in NMP at 80° C. for 15 min and rinsing in NMP, acetone, and IPA.

Finally, the wafer was diced with a Disco DAD3240 automatic saw into nine 12×12 mm substrates. Each substrate contained five bowtie device arrays and one reference device in a compact central region, with large side pads for electrical access.

### HgSe/CdS CQDs Film Preparation

The substrate was heated to 40° C. One drop of the HgSe/CdS in TCE solution was drop casted onto the substrate with a glass Pasteur pipette. The substrate was lightly rotated to keep the solution covering the substrate. The excess solution was wicked away. 5% EdT in IPA solution was dropped to cover the film for 10 s. The film was rinsed with IPA and dried with nitrogen. The procedure was repeated to reach the desired film thickness.

### EL Measurements

The sample was electrically driven using a Keithley model 6221 AC and DC current source. The voltage was monitored with an oscilloscope. The emitted signal was sent through a home-made step-scan interferometer. The signal was then detected by an MCT detector and a lock-in amplifier LIA-MV-150. The obtained spectrum was corrected for the instrumental spectral response, which was obtained by comparing the experimental and calculated blackbody emission.

### Efficiency Determination

An absolute PLQY measurement was performed for a reference sample (undoped HgSe/CdS dots on Al substrate) that emitted at around 4500 cm⁻¹. The absolute integrated PLQY of the reference sample was measured by inserting it inside a Spectralon integrating sphere. The PL and 808 nm signals were measured with a PbSe detector, with or without a silicon window filter, and with or without the sample. The quantum efficiency of the PbSe detector was assumed to be the same at all energies, in the short-wave infrared, and at 808 nm. The emission spectra of the reference sample and the devices were measured. The area of the emission peaks was integrated to give the emitted photon flux. The absorbed 808 nm laser photons were measured with a power meter. The quantum efficiency of the sample was determined relative to the reference sample, after normalizing the emitted photon flux and the absorbed 808 nm laser photons. The electroluminescence external quantum efficiency was measured in the same way using the current. The reference sample and the measured devices were assumed to have similar angular distributions.

### Geometric Parameters of the Metallic Structure

The metallic structure comprised the bowtie antennas and the interdigitated electrodes. Its geometric parameters are given in FIG. 12. This structure had a 3.8 μm periodicity along the x-axis and a 3.2 μm periodicity along the y-axis.

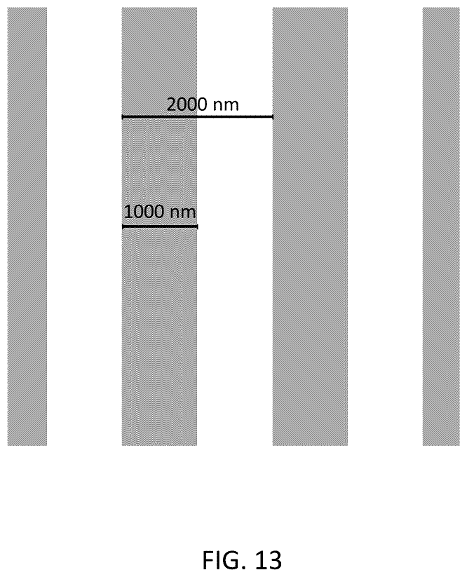

In the case of the reference device (FIG. 13), the electrodes were interdigitated gold electrodes with 1 μm width and 2 μm periodicity fabricated on a sapphire substrate.

### Simulation of the Bowtie LED

The relative radiative decay rate

$${γ}_{r}^{X , Y , Z} ( \vec{r} ) / {γ}_{r}^{0}$$

and relative non-radiative decay rate

$${γ}_{nr}^{metal , X , Y , Z} ( \vec{r} ) / {γ}_{r}^{0}$$

were mapped across the bowtie device for the 3 dipole orientations X, Y and Z (data not shown). The maps extended over a unit cell of the metallic structure (3.8 μm×3.2 μm), centered on the bowtie antenna.

The bowtie antenna provided a substantial enhancement to the radiative decay rate for emitters placed in the nanogap, with a maximum

$${γ}_{r}^{Y} / {γ}_{r}^{0} = 2500$$

at the best position for dipoles oriented along the Y-axis. Outside of this hotspot, the emitter's emission intensity was orders of magnitude lower.

The losses to the metallic structure were also enhanced within the nanogap and were particularly strong close to metallic surfaces, reaching

$${γ}_{nr}^{metal , Y} / {γ}_{r}^{0} = 1500$$

on the edge of the antenna in the nanogap.

The bowtie antenna generated substantial losses, but these losses were comparable to the losses inherent to the CQD film

$${γ}_{nr}^{0} / {γ}_{r}^{0} \approx 650.$$

Hence, the antenna did no substantially boost non-radiative decay within the CQD film while it increased the radiative decay rate of the CQDs by up to 3 orders of magnitude. Therefore, the efficiency of the device can be vastly enhanced despite the lossy nature of the plasmonic resonance of the bowtie antenna.

For each dipole orientation, PLQY^{X,Y,Z}(\vec{r}) was calculated from the maps of

$${γ}_{γ}^{X , Y , Z} ( \vec{r} ) / {γ}_{r}^{0} and {γ}_{nr}^{metal , X , Y , Z} ( \vec{r} ) / {γ}_{r}^{0}$$

(see method section). The best PLQY was obtained for
dipoles oriented along the Y-axis and positioned in the hotspot of the bowtie antenna.

The extraction efficiency

$${η}_{ex}^{X , Y , Z} ( \vec{r} , λ )$$

at 5 μm was also obtained (data not shown), which corresponds to the peak of the bowtie antenna resonance.

The map of PLQY_{best}(\vec{r}) was calculated from the maps of PLQY^{X,Y,Z}(\vec{r}) by selecting the highest value at each position. This case corresponds to the best performance achievable with the device, obtained for ideally oriented dipole emitters. (See FIG. 9B.) Using this map to calculate the simulated PCE (see method section, above) PCE=10.5% was obtained.

The map of PLQY_{average}(\vec{r}) was calculated from the maps of PLQY^{X,Y,Z}(\vec{r}) by averaging the values at each position over the 3 dipoles orientation. This case corresponds to a device with randomly oriented dipole emitters. Using this map to calculate the simulated PCE (see method section, above) PCE=4% was obtained.

### Simulation of the Reference LED

The relative radiative decay rate

$${γ}_{r}^{X , Y , Z} ( \vec{r} ) / {γ}_{r}^{0}$$

and relative non-radiative decay rate

$${γ}_{n r}^{metal , X , Y , Z} ( \vec{r} ) / {γ}_{r}^{0}$$

were mapped across the reference device for the 3 dipole orientations X, Y and Z (data not shown). The maps extended over a periodic unit of the interdigitated electrodes along the X-axis (2 μm) and an arbitrary 2 μm along the Y-axis. The X-Axis was centered on a conductive channel of the device, enclosed by two metallic electrodes.

The interdigitated electrodes did not significantly alter the radiative decay rate of the emitters. The maximum enhancement,

$${γ}_{r}^{X} / {γ}_{r}^{0} = 4 ,$$

occurred for dipoles oriented along the X-axis near the gold electrodes. Losses to the metallic electrodes were negligible compared to the intrinsic nonradiative losses of the CQD film

$$( {γ}_{n r}^{0} / {γ}_{r}^{0} \approx 650 ) .$$

Therefore, the reference device structure provided a reliable platform to characterize the emission of the CQD film under conditions where the device architecture had only a minimal influence on the CQDs' optical properties.

For each dipole orientation, PLQY^{X,Y,Z}(\vec{r}) was calculated from the maps of

$${γ}_{r}^{X , Y , Z} ( \vec{r} ) / {γ}_{r}^{0} and {γ}_{n r}^{metal , X , Y , Z} ( \vec{r} ) / {γ}_{r}^{0}$$

(see method section).

The extraction efficiency

$${η}_{ex}^{X , Y , Z} ( \vec{r} , λ )$$

at 5 μm was also obtained (data not shown).

The map of PLQY_{best}(\vec{r}) was calculated from the maps of PLQY^{X,Y,Z}(\vec{r}) by selecting the highest value at each position. Using this map to calculate the simulated PCE (see method section) PCE=0.06% was obtained.

The map of PLQY_{average}(\vec{r}) was calculated from the maps of PLQY^{X,Y,Z}(\vec{r}) by averaging the values at each position over the 3 dipoles orientation. Using this map to calculate the simulated PCE (see method section, above) PCE=0.03% was obtained.

The simulated PCE can be compared to the 0.03% external PLQY measured with a CQD film deposited on aluminum and to the ˜0.02% PCE measured with the experimental reference device.

The simulated electrical power density across the reference device for an input electrical power of 3 mW over a 300 μm×300 μm device was obtained (data not shown). Its distribution was homogeneous across the conductive channels of the device.

The simulated electroluminescence spectral power density of the reference device for TE polarized emission (along the Y-axis) and TM polarized emission (along the X-axis) was obtained (data not shown).

### Absorbance and PL Spectra of HgSe/CdS Dots

The HgSe cores with a diameter of 4.8 nm were synthesized. A thin CdS shell was grown by 4 cycles of colloidal atomic layer deposition (cALD). The HgSe/CdS dots had a diameter of 6.2 nm. The CdS shell improved the PLQY and controlled the doping level. The absorbance spectrum of the HgSe/CdS dots was measured by making a film on a ZnSe ATR plate and exchanging the ligands to EdT (data not shown). Tntraband absorption peak was around 2200 cm⁻¹ with an FWHM of 700 cm⁻¹. The first interband peak around 5000 cm⁻¹ was partially quenched due to the n-doping. The doping level was about 1.5 electron/dot. The PL spectrum was measured on an Al substrate. The intraband PL peaked around 2000 cm⁻¹ with an FWHM of 620 cm⁻¹. There was a weak interband peak around 4500 cm⁻¹. The external intraband PLQY of the film on aluminum was determined to be about 0.03%.

### Absorbance and PL Spectra of HgSe Cores

The absorption and PL spectra of the HgSe cores were obtained (data not shown). The dots had an average doping of about 3 electron/dot. The intraband absorption peak had contributions from both S to P and P to higher states. It peaked around 2100 cm⁻¹ with an FWHM of 750 cm⁻¹. The first interband peak around 5000 cm⁻¹ was nearly fully quenched. The intraband PL peak also came from both S to P and P to higher states, resulting in an unsymmetrical shape. The interband transition did not show PL since the doping was more than 2 electron/dot.

### Bowtie LED Electroluminescence Spectra

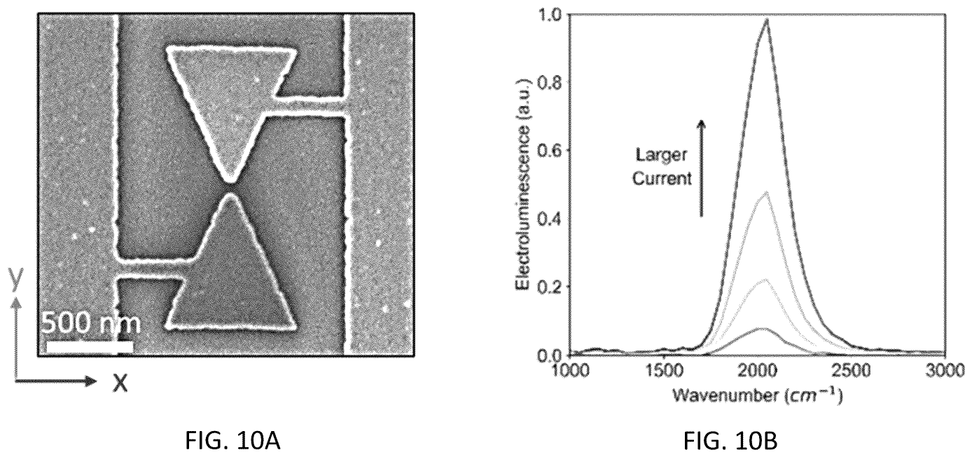

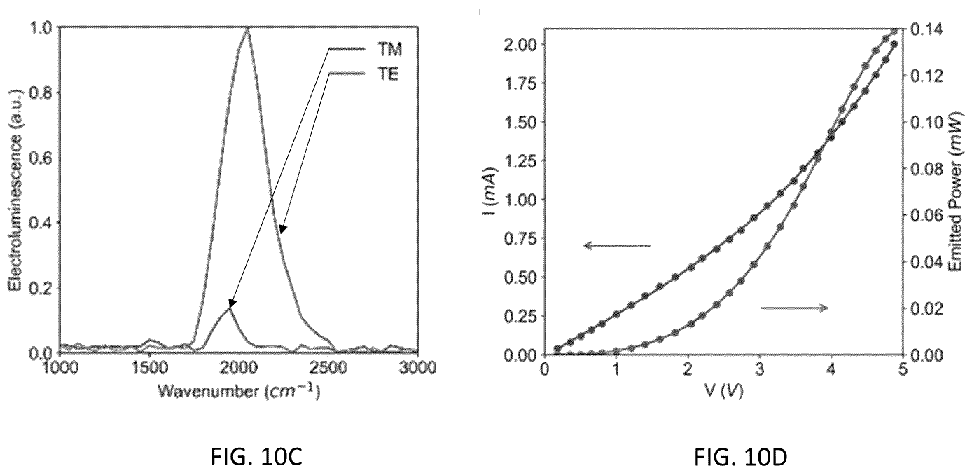

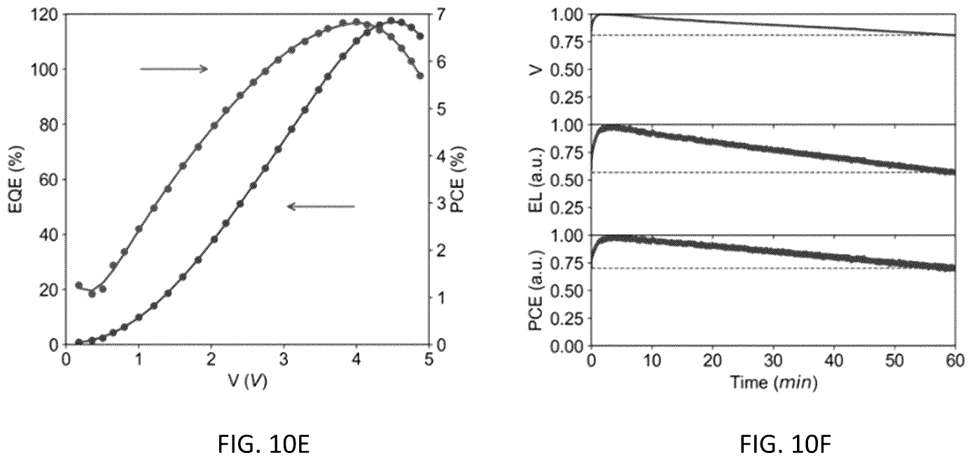

The same EL spectra as presented in FIG. 10B but displayed on a larger spectral scale was examined (not shown). It was observed that there was no measurable interband EL signal.

### Bowtie Antenna Device Degradation Under Bias>5V

Applying biases over 5V damaged the bowtie LEDs. This is because the CQD film was damaged when exposed to large electrical power. Since the bowtie nanogap focused the electrical power, this was the part of the film where damage occurred. This damage resulted in limited brightness and stability. Images showed that the damage was limited to the nanogap region, and the damage appeared to be the removal of the CQD film. All the nanogaps did not get damaged simultaneously, but rather progressively, one after the other.

### Reference Device Measurements

A reference device was fabricated with interdigitated electrodes having a 1 μm gap and 1 μm width, covering an area of 250 μm×250 μm. (See FIG. 13.) The electrode spacing was chosen to minimally affect the emission lineshape and efficiency. A thin film of the same HgSe/CdS quantum dots, with comparable thickness, was deposited. Under applied current, the device emitted at 2000 cm⁻¹ with a full width at half maximum (FWHM) of 500 cm⁻¹. EL was comparable for both polarizations. The EQE increased with applied bias, and the PCE rose slightly. At the maximum applied current of 10.2 mA, the bias reached 20.5 V, producing 0.013 mW of emitted power, with an EQE of 2.1% and a PCE of 0.025%. The device PCE was consistent with the measured PLQY of the dot film.

### EL Response Under Time-Modulated Bias

The real-time EL response under different bias waveforms was examined (data not shown). The results showed that the device was driven by a positive bias modulated with a sine wave at 20, 40, and 80 kHz. The low bias level varied slightly due to limitations of the current source. The EL signal closely followed both the waveform and frequency of the applied bias, showing similar intensity across all frequencies. These results confirmed the DC nature of the EL and demonstrated its fast response.

In some experiments, a negative bias was applied, and the EL signal again tracked the waveform and frequency of the bias (data not shown). Under an AC bias, the EL signal oscillated at twice the frequency of the applied bias, emitting at both peaks and valleys with comparable intensity (data not shown). These observations indicated that the intraband EL was independent of bias polarity and thus was evidence of the cascade EL mechanism.

### Substrate Cleaning and Reuse

The EL was first measured on a bowtie substrate. The CQD film was then removed by heating the substrate in an H₂O₂/acetic acid solution, followed by deposition of a new film of the same CQDs. The second measurement showed overall similar performance, with slightly lower conductivity and slightly higher efficiencies. This trend was observed across multiple substrates, with the first cleaning typically resulting in approximately twice the resistance and a ˜30% increase in efficiency. This improvement might be due to the cleaning process removing defects, such as gold particles left from the lift-off process during nanofabrication, and slightly roughening the gold edges. Substrates could be cleaned and reused multiple times, although subsequent cleanings produced much smaller changes compared to the first one.

### Low Temperature Measurements

The device was placed in a cryostat for low-temperature measurements. The emission from the bowtie device was 30% narrower than at room temperature and still determined by the photonic resonance, suggesting improved cavity quality, likely due to reduced losses in the gold at lower temperatures. Both the reference and bowtie devices exhibited lower and more nonlinear conductivity at 80 K.

For the reference device, the efficiency decreased by roughly a factor of four. Taking the average applied bias per dot as the applied bias divided by the gap size and multiplied by the dot diameter, the reference device was operated up to 0.2 V/dot, which was smaller than the S-P energy (0.25 eV). The efficiency drop at 80K was assigned to the energy level alignment requirement for the cascade operation, which was less thermally facilitated at 80K.

For the bowtie device, the efficiency slightly increased at 80 K. This was primarily assigned to the improved cavity quality, while the bowtie device was operated up to 0.5 V/dot so that the cascade resonance condition was better satisfied. However, in the working range of 0-0.2 V/dot, the bowtie device at 80 K still showed similar or better efficiency than at room temperatures. This was tentatively attributed to the non-uniformity of the bias drop across the junction which facilitated the cascade.

### Variation of the Shell Thickness

HgSe quantum dots with varying CdS shell thicknesses were prepared. Increasing the shell thickness improved the PLQY but reduced conductivity. The same substrate was cleaned and reused to allow direct comparison between different dots, and similar films were deposited. For the reference device, at the same applied bias, thicker shells resulted in lower current but higher PCE. On the bowtie substrate, the conductivity followed a similar trend, while the EQE and PCE remained largely unaffected by shell thickness, particularly at low biases.

### Characterization of a Commercial Mid-Infrared LED

A commercial 4.3 μm Hamamatsu IR LED L15895-0430M was tested with the setup described herein The LED was driven by 20 kHz square shape currents. The emission spectra were measured as described in the methods, and the emitted power was further calculated. The applied current was limited to 40 mA, since there was temperature instability at larger currents. Experimental results were obtained and compared with the results from the datasheets (data not shown). At the same current, the applied voltage was about 5% larger than the reported values, and the emitted power was about 30% lower. The measured results showed overall good

### Results and Discussion

This Example further leverages the results shown in Examples 1-3, above, including the observation of cascade electroluminescence using HgSe/CdS colloidal quantum dots. By applying a large bias across a random close-packed film of quantum dots, mid-infrared light was emitted at the energy of the S_{1/2}-P_{1/2} intraband transition, which were the two lowest quantum confined states in the conduction band of the spherical quantum dots. The process was compatible with planar electrodes, robust with changing the electrode separation, and consistent with a cascade process where the electrons tunneled from dot to dot, and with the high bias were injected into the P state followed by relaxation to the S state. The power conversion efficiency (PCE), however, remained below 0.1%, limited by the slow P-S radiative rate (100 s of ns) compared to the non-radiative rate (100 s of ps). Thus, structures that could boost the radiative rate were sought to benefit the efficiency. Hence, this Example explored the use a planar bowtie antenna as a pair of electrodes to inject carriers into a film of CQD that coats the electrodes.

The antenna was designed using optical and electrical simulations. The optimized architecture is shown in FIGS. 9A and 12. It consisted of a periodic array of gold bowtie antennas placed between interdigitated electrodes. The total length of the bowtie antenna was 1.7 μm, and the nanogap defined therein was 80 nm in length and 50 nm in width. The array had a 3.2 μm periodicity along the longitudinal dimension of the electrodes and a 3.8 μm periodicity perpendicular to this dimension. The structure was formed on top of a 1 μm thick SiO₂ optical spacer and a gold back reflector, enhancing the electric field in the bowtie array layer through a broad quarter-wave resonance around 5.6 μm. A 60 nm thick HgSe/CdS CQD film covered the antennas and electrodes, thus filling the bowtie nanogap.

This bowtie structure supported a strong optical resonance around 5 μm, with greatly enhanced optical electric field within the nanogap. The simulation showed a radiative decay rate γᵣ up to 2500 times faster than in vacuum

$${γ}_{r}^{0} ,$$

for the best dipole orientation (data not shown). There was also a fast non radiative Joule loss in the metal

$${γ}_{n r}^{metal} ,$$

which had the same order of magnitude but remained slower than γᵣ in most places. In addition, the simulations included the intrinsic non-radiative decay rate of the CQD film

$${γ}_{nr}^{0} .$$

In the simulations, the influence of the antenna on

$${γ}_{nr}^{0}$$

was not considered. These losses should not be affected as long as the emitters are further than a few nanometers from the antenna.

The photoluminescence quantum yield

$$PLQY = {γ}_{r} / ( {γ}_{r} + {γ}_{nr}^{metal} + {γ}_{nr}^{0} )$$

was calculated from the simulated ratio

$${γ}_{r} / {γ}_{r}^{0} and {γ}_{nr}^{metal} / {γ}_{r}^{0} \cdot {γ}_{nr}^{0} / {γ}_{r}^{0} = 650$$

was taken, as estimated from the low external PLQY measured with a CQD film on an aluminum surface (see method section, above). FIG. 9B shows a map of the calculated PLQY across the device for ideally oriented dipoles. The large radiative rate enhancement can then, from simulations, boost the PLQY of the CQDs from 0.1% with no antenna to 50% when positioned in the nanogap (other data not shown).

The electrical connections to the bowtie consisted of 100 nm wide gold leads. The optimal positions of the leads were determined by the simulations, and they were placed in regions of weak optical field to minimize the disturbance to the antenna resonance. To simulate the efficiency, the electrical transport assumed an ohmic material.

The emission intensity was proportional to the current density and was also proportional to the electrical field through the cascade gain; therefore, the electrical power density was the relevant quantity to simulate the device efficiency. FIG. 9C shows the map of the simulated electrical power density P=J×E_{V}, where/is the current density and E_{V} is the electric field applied by the electrodes across the device. It shows that the electrical power was channeled mostly into the nanogap where the radiative relaxation was also the most efficient, as needed to maximize the electroluminescence of the device. About 20% of the electrical power input in the device flowed through the nanogap, which represented only 0.03% of the volume of the CQD film. The rest of the electrical power flowed between the side edge of the antenna and the interdigitated electrodes.

The same simulations were performed for a reference device consisting of the same CQD film deposited on interdigitated electrodes on a sapphire substrate. The electrodes were 1 μm in width and had a 2 μm periodicity (FIG. 13). This geometry did not substantially influence the emission properties of the CQDs (see “Simulation of the reference LED” section, above) and serves as a reference to quantify the performance boost provided by the bowtie antenna.

The simulated maps of PLQY and electrical power were combined to calculate a simulated PCE for the bowtie device and reference device (see methods section, above). For the bowtie device, the calculated PCE was 10% when considering ideally oriented dipole emitters. Indeed, the relaxation was between the 1P_{1/2} and 1S_{1/2} states, and the otherwise isotropic emission became directed in the direction of the fastest radiative rate. This was similar to the best dipole orientation condition. For the reference device, the calculated PCE was 0.06%, which can be compared to the 0.03% external PLQY measured with a CQD film deposited on aluminum.

The simulated maps of PLQY and electrical power were also used to calculate the electroluminescence power spectral density of the device. FIG. 9D shows a comparison of the simulated emission spectrum of the bowtie antenna device and the reference device. The presented spectra corresponded to EL collected by F/2 optics, mimicking the experimental setup. The bowtie resonance substantially boosted the 5 μm emission of CQDs and narrowed the device emission (FWHM=215 cm⁻¹) compared to the reference (FWHM=500 cm⁻¹), as shown in FIG. 9D. The bowtie device emission was also strongly polarized (FIG. 9E) along the antenna (Y-axis), roughly 15 times stronger than for perpendicular (X-axis) emission.

These simulation predictions were then compared with the experimental results from fabricated devices. FIG. 10A shows an SEM image of the bowtie antenna structure. The overall device area was 300 μm×300 μm, containing 7246 bowtie antennas. The device was tested at room temperature in air, driven with a current source. The emitted EL signal was collected with an F/2 off-axis parabolic gold mirror, sent through a step-scan Michelson interferometer, and detected with a liquid-nitrogen-cooled MCT detector. The signal was then analyzed with a lock-in amplifier. The measured EL spectra are shown in FIG. 10B with intensity increasing with larger applied current. The emission FWHM was 290 cm⁻¹ which was slightly larger than predicted by the simulations but narrower than the emission without the resonant structure (500 cm⁻¹). The emission was strongly polarized (FIG. 10C): ten times stronger for emission polarized along the antenna (X-axis) than perpendicular to the antenna (Y-axis), consistent with the simulations.

I-V-EL characteristics are shown in FIGS. 10D-10E where the device was driven by an ac current. The I-V curve (FIG. 10D) was slightly less non-linear than the reference (data not shown). This may have been due to leakage currents in parallel to the more nonlinear cascade current. FIG. 10D shows the EL intensity as a function of voltage, which was very nonlinear, similar to prior observations. The knee, around 2.5 V, was roughly consistent with the gap dimension (80 nm), the dot diameter (6.2 nm) and the P-S energy gap (0.25 eV).

The mean emitted power was determined by assuming a lambertian emission and was calibrated by the emission of a photoluminescent sample for which the absolute quantum yield has been measured (see method section, above). It increased with larger bias, reaching 0.14 mW at the higher bias (FIG. 10E). The external electron to photon quantum efficiency (EQE) increased with bias and decreased slightly at large biases, with a peak value of 120%, as shown in FIG. 10F. The EQE increased with bias because of the cascade gain. The PCE also increased with bias, reaching a peak of 6.8% around 4 V (FIG. 10F).

The devices were damaged by applying larger biases. SEM imaging after testing at 5V showed that the CQD film was damaged around many of the bowtie nanogaps (data not shown). This further confirmed that a large part of the electrical power was funneled through the nanogap. At lower bias, this damage was not observed, but the efficiency decreased over time. FIG. 10F shows the time evolution of the bias and EL at a constant AC current of 0.5 mA. The bias, EL signal, and PCE increased in the first few minutes and decreased afterwards. The PCE remained at 75% of the highest value after 60 min. The time variation might relate to the redistribution of current density within the device, the stability of the dots, and changes in doping.

A reference device was fabricated to characterize the emission without optical enhancement (FIG. 13). The reference device consisted of interdigitated electrodes with 1 μm gap and 1 μm width, fabricated on a sapphire substrate, like the simulated reference discussed above. The device area was 250 μm×250 μm. The substrate was coated with a 60 nm thick film of the same CQDs. Under bias, the device showed emission at 2000 cm⁻¹ with an FWHM of 500 cm⁻¹ and negligible polarization dependence. The efficiency increased with bias, with 2.1% EQE and 0.025% PCE under 20.5 V. The bowtie design therefore increased the PCE 270-fold, which was fairly consistent with the improvement predicted from the simulation.

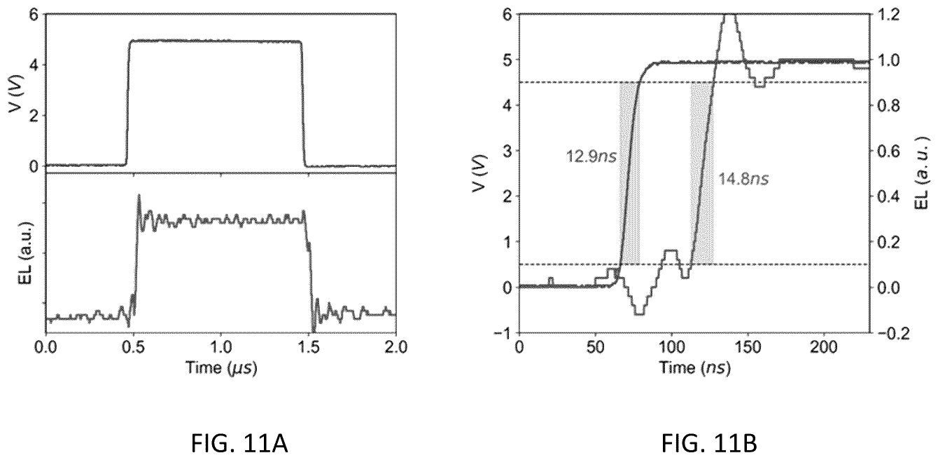

The time response of the devices was not simulated, but the direct experimental time resolution of the EL signal showed that it is likely below 10 ns. Under 1 μs voltage square pulses at 5 V, the emission signal followed the shape of the voltage closely. This excludes the possibilities that the emission arises from AC drive or thermal emission. (FIG. 11A). The rise time of the EL was around 15 ns, limited by the MCT detector response and input pulse (FIG. 11B). Additional real-time EL response under bias modulation (data not shown) confirmed that the EL signal had no polarity.

The best device PCE of 6.8% was two orders of magnitude higher than the LED made with similar CQDs as described in Example 3, above. The efficiency was also much higher than commercial epitaxial cascade quantum well LEDs, which have 0.1% PCE at 5.2 μm.

The PCE of the devices showed variations, as expected from changes in the quality of the electrode fabrication and CQD films. With 20 devices measured, including various adjustments to the CQD material and bowtie geometry, 19 devices had PCE>1%, and 12 devices had PCE>3%. The substrates could be reused (data not shown) by removing the CQDs with a warm H₂O₂/acetic acid solution for a minute and depositing a new CQD film. Interestingly, performance improved after the first cleaning, with slightly larger EQE and PCE.

The influence of the CdS shell thickness was also investigated (data not shown). While thicker shells reduced the CQD film conductivity, they also reduced the non-radiative decay rate of the material by reducing energy transfer to absorbers outside of the dots. For the reference device, the EQE and PCE were higher with thicker shells, which was consistent with the increased PLQY of the CQDs. However, the bowtie device showed weak dependence of the EQE and PCE on shell thickness. This can be understood since γᵣ and

$${γ}_{nr}^{metal}$$

were expected to already be both faster than

$${γ}_{nr}^{0} ,$$

and it also indirectly confirmed that the Purcell enhancement did not strongly affect

$${γ}_{nr}^{0} .$$

Devices were tested at low temperature in a cryostat at 80 K (data not shown). Compared to room temperature, the PCE of the reference device decreased roughly 4 times, while it increased 30% for the bowtie device. The I-V curves were much more nonlinear, which was assigned to the cascade resonance condition being less thermally affected. The EL of the bowtie devices narrowed further to 205 cm⁻¹, which was assigned to the improved quality factor as the metal became less lossy.

Simulations had indicated earlier that only 20% of the current flowed across the nanogaps. Therefore, insulating the electrodes outside the gap could further increase in PCE and power by an expected 2-fold. The devices were not yet brighter than commercial LEDs because the mean power emitted by the CQD device of area 0.1 mm² was about 0.15 mW, compared to the commercial quantum well LEDs, which can emit 1 mW. The CQD device brightness was limited by the maximum sustainable mean electrical power of 3 mW, compared to 1 W for the solid state devices. The equivalent blackbody temperature of the CQD LED was estimated as 1200 K, considering the bandwidth from 1900 cm⁻¹ to 2190 cm⁻¹. The high apparent temperature and facile fabrication enables fabrication of infrared displays with possible applications as simulators. The maximum current density reached in the devices was estimated at 5 kA/cm², in the nanogap. The bowtie structure is thought to benefit from fast lateral heat dissipation, because this was a large current density for CQDs devices. That current density over the film thickness and nanogap width, and a dot physical cross section of 5×10⁻¹³ cm², also implied that an electron flowed through the dots about every 100 ps.

### CONCLUSIONS

To conclude, this Example combined intraband mid-IR emitting colloidal quantum dots with the Purcell enhancement from bowtie antennas, achieving record efficiency of spontaneous electroluminescence at 5 micrometers, with good agreement between simulations and experimental results. The eminently practical combination of solution-processed colloidal quantum dots and nanofabricated substrates is an opportunity to harness the Purcell enhancement, to improve emitting and detecting infrared devices, and to create new infrared electrooptical devices.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.” If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

The foregoing description of illustrative embodiments of the disclosure has been presented for purposes of illustration and of description. It is not intended to be exhaustive or to limit the disclosure to the precise form disclosed, and modifications and variations are possible in light of the above teachings or may be acquired from practice of the disclosure. The embodiments were chosen and described in order to explain the principles of the disclosure and as practical applications of the disclosure to enable one skilled in the art to utilize the disclosure in various embodiments and with various modifications as suited to the particular use contemplated. It is intended that the scope of the disclosure be defined by the claims appended hereto and their equivalents.

What is claimed is:

1. A method of generating light, the method comprising applying an electrical bias to an active region of a quantum dot cascade light emitting device comprising:
the active region comprising a film of close-packed, doped, colloidal quantum dots, the quantum dots comprising a core semiconductor characterized by an energy band having quantum states defining an intraband transition between a high energy quantum state and a low energy quantum state, and
a pair of electrodes configured to apply the electrical bias,
wherein the active region emits light under the electrical bias as carriers undergo the intraband transitions in the core semiconductor of quantum dots in the film, tunnel to other quantum dots in the film, and undergo additional intraband transitions in the core semiconductor of the other quantum dots in the film.

2. The method of claim 1, wherein the energy band is dispersive by more than 0.3 eV and has a minimum lower than −3 eV with respect to vacuum.

3. The method of claim 2, wherein the high energy quantum state of the intraband transition has a greater degeneracy than the low energy quantum state of the intraband transition.

4. The method of claim 1, wherein the quantum dots are characterized by a doping level n of less than 2.

5. The method of claim 1, wherein the quantum dots are core-shell quantum dots further comprising a shell semiconductor around the core semiconductor.

6. The method of claim 5, wherein the shell semiconductor has a shell thickness of less than 10 monolayers of the shell semiconductor.

7. The method of claim 1, wherein the light is mid-infrared light.

8. The method of claim 1, wherein the light has a wavelength in a range of from 4 μm to 7 μm.

9. The method of claim 1, wherein the active region has a channel length of at least 1 μm.

10. The method of claim 1, wherein the electrical bias is greater than 10 V.

11. The method of claim 1, wherein the quantum dot cascade light emitting device exhibits greater electroluminescent external quantum efficiency (EL EQE) as compared to photoluminescence external quantum efficiency (PL EQE).

12. The method of claim 11, wherein the EL EQE is at least 50 times greater than the PL EQE.

13. The method of claim 1, wherein the quantum dot cascade light emitting device further comprises a planar interdigitated electrode layer below a surface of the active region, the planar interdigitated electrode layer comprising the pair of electrodes.

14. The method of claim 13, wherein the planar interdigitated electrode layer further comprises an array of nanoantennas positioned between gaps defined between electrodes of the planar interdigitated electrode layer.

15. The method of claim 14, wherein the nanoantennas comprise bowtie antennas, each bowtie antenna defining a bowtie nanogap, wherein at least some of the quantum dots are positioned over each bowtie nanogap.

16. The method of claim 15, wherein the quantum dot cascade light emitting device further comprises a spacer layer below the planar interdigitated electrode layer and a back reflector layer below the spacer layer.

17. The method of claim 1, wherein the quantum dot cascade light emitting device emits the light at constant current.

18. A quantum dot cascade light emitting device comprising:
an active region comprising a film of close-packed, doped, colloidal quantum dots, the quantum dots comprising a core semiconductor characterized by an energy band having quantum states defining an intraband transition between a high energy quantum state and a low energy quantum state; and
a pair of electrodes configured to apply an electrical bias to the active region,
wherein the active region is configured to emit light under the electrical bias as carriers undergo the intraband transitions in the core semiconductor of quantum dots in the film, tunnel to other quantum dots in the film, and undergo additional intraband transitions in the core semiconductor of the other quantum dots in the film.

19. The quantum dot cascade light emitting device of claim 18, further comprising a planar interdigitated electrode layer below a surface of the active region, the planar interdigitated electrode layer comprising the pair of electrodes and an array of nanoantennas positioned between gaps defined between electrodes of the planar interdigitated electrode layer.

20. The quantum dot cascade light emitting device of claim 19, wherein the nanoantennas comprise bowtie antennas, each bowtie antenna defining a bowtie nanogap, wherein at least some of the quantum dots are positioned over each bowtie nanogap, the quantum dot cascade light emitting device further comprises a spacer layer below the planar interdigitated electrode layer and a back reflector layer below the spacer layer.
